(19) United States
(12) Patent Application Publication
(10) Pub. No.: US 2026/0032886 A1
(43) Pub. Date: Jan. 29, 2026

(54) SEMICONDUCTOR MEMORY DEVICE

(71) Applicant: Samsung Electronics Co., Ltd., Suwon-si (KR)

(72) Inventors: Eunsuk Jang, Suwon-si (KR); Jinwoo Han, Suwon-si (KR); Hyebin Kim, Suwon-si (KR); Gyuhwan Oh, Suwon-si (KR)

(21) Appl. No.: 19/045,164

(22) Filed: Feb. 4, 2025

(30) Foreign Application Priority Data
Jul. 23, 2024 (KR) 10-2024-0097520

(51) Int. Cl. H10B 12/00

(52) U.S. Cl. CPC H10B 12/482; H10B 12/03; H10B 12/05

(57) ABSTRACT

There are provided a semiconductor memory device and a method of manufacturing the same. The semiconductor memory device includes a semiconductor pattern extending in a first horizontal direction on a substrate and including a channel region, a first impurity region, and a second impurity region, wherein the first impurity region and the second impurity region are arranged in the first horizontal direction with the channel region therebetween, the first impurity region of the semiconductor pattern includes a first portion in contact with a bit line and a second portion connected to the first portion, the first portion has a varying horizontal width in a second horizontal direction, and the varying horizontal width of the first portion continuously varies along the first horizontal direction.

### CROSS-REFERENCE TO RELATED APPLICATION

This application is based on and claims priority under 35 U.S.C. § 119 to Korean Patent Application No. 10-2024-0097520, filed on Jul. 23, 2024, in the Korean Intellectual Property Office, the disclosure of which is incorporated by reference herein in its entirety.

### BACKGROUND

The inventive concept relates to a semiconductor memory device, and more particularly, to a three-dimensional semiconductor memory device.

The need for miniaturization, multifunctionality, and high performance in electronic products requires high-capacity semiconductor memory devices. Also, in order to provide high-capacity semiconductor memory devices, increased integration is required. Accordingly, a three-dimensional semiconductor memory device with increased memory capacity by stacking a plurality of memory cells in a vertical direction on a substrate has been proposed.

### SUMMARY

Aspects of the inventive concept provide a three-dimensional semiconductor memory device with reduced parasitic capacitance and increased reliability by forming a horizontal width of a bit line and a horizontal width of a portion of a semiconductor pattern adjacent to the bit line to be relatively narrow.

The objective of the inventive concept is not limited thereto, and other objectives may be clearly understood by those skilled in the art from the following.

According to an aspect of the inventive concept, there is provided a semiconductor memory device including a substrate, a semiconductor pattern extending in a first horizontal direction on the substrate and including a channel region, a first impurity region, and a second impurity region, wherein the first impurity region and the second impurity region are arranged in the first horizontal direction with the channel region therebetween, a word line surrounding the channel region of the semiconductor pattern and extending in a second horizontal direction crossing the first horizontal direction, a bit line in contact with the first impurity region of the semiconductor pattern and extending in a vertical direction, and a cell capacitor in contact with the second impurity region of the semiconductor pattern, wherein the first impurity region of the semiconductor pattern includes a first portion in contact with the bit line and a second portion connected to the first portion, the first portion has a varying horizontal width in the second horizontal direction, and the varying horizontal width of the first portion continuously varies along the first horizontal direction.

According to another aspect of the inventive concept, there is provided a semiconductor memory device including a substrate, a plurality of word lines arranged apart from each other in a first horizontal direction on the substrate and extending in a second horizontal direction crossing the first horizontal direction, a bit line arranged between a first set of word lines of the plurality of word lines and a second set of word lines of the plurality of word lines and extending in a vertical direction, a plurality of cell capacitors spaced apart from the bit line with the first set of word lines of the plurality of word lines therebetween, and a plurality of semiconductor patterns each including a channel region overlapping each of the word lines of the first set of word lines in the vertical direction, a first impurity region connected to the bit line, and a second impurity region connected to a respective cell capacitor of the plurality of cell capacitors, wherein each first impurity region includes a first portion in contact with the bit line and a second portion spaced apart from the bit line with the first portion therebetween, the first portion has a horizontal width in the second horizontal direction, the second portion has a horizontal width in the second horizontal direction that is greater than a minimum value of the horizontal width in the second horizontal direction of the first portion, and the bit line has a horizontal width in the second horizontal direction that is less than the horizontal width in the second horizontal direction of the second portion.

According to an aspect of the inventive concept, there is provided a semiconductor memory device including a substrate, a semiconductor pattern extending in a first horizontal direction on the substrate and including a channel region, a first impurity region, and a second impurity region, wherein the first impurity region and the second impurity region are arranged in the first horizontal direction with the channel region therebetween, a word line surrounding the channel region of the semiconductor pattern and extending in a second horizontal direction crossing the first horizontal direction, a bit line in contact with the first impurity region of the semiconductor pattern and extending in a vertical direction, and a cell capacitor in contact with the second impurity region of the semiconductor pattern, wherein the first impurity region of the semiconductor pattern includes a first portion in contact with the bit line and a second portion spaced apart from the bit line with the first portion therebetween, the first portion has first side walls opposite to each other in the second horizontal direction, the second portion has second side walls opposite to each other in the second horizontal direction, each of the first side walls has a curvature, and the second side walls are flat.

### BRIEF DESCRIPTION OF THE DRAWINGS

Embodiments will be more clearly understood from the following detailed description taken in conjunction with the accompanying drawings in which:

FIG. 1 is a block diagram schematically showing a semiconductor memory device according to some embodiments;

FIG. 2A is a circuit diagram showing a memory cell array shown in FIG. 1;

FIG. 2B is a circuit diagram showing an antifuse cell array shown in FIG. 1;

FIG. 3 is a perspective view showing a semiconductor memory device according to some embodiments;

FIG. 4 is a schematic perspective view showing a memory cell region of the semiconductor memory device according to some embodiments;

FIG. 5A is a layout diagram showing the memory cell region of the semiconductor memory device according to some embodiments;

FIG. 5B is an enlarged view of a portion CX1 of FIG. 5A;

FIG. 6A is a cross-sectional view taken along a line A1-A1′ of FIG. 4;

FIG. 6B is an enlarged view of a portion CX2 of FIG. 7A;

FIG. 7 is a cross-sectional view taken along a line B1-B1′ of FIG. 4;

FIG. 8 is a cross-sectional view taken along a line C1-C1′ of FIG. 4;

FIG. 9 is a schematic perspective view showing a memory cell region of a semiconductor memory device according to some embodiments;

FIG. 10 is a layout diagram showing the memory cell region of the semiconductor memory device according to some embodiments;

FIG. 11 is a cross-sectional view taken along a line A2-A2′ of FIG. 9;

FIG. 12A is a diagram for explaining a semiconductor memory device according to some embodiments;

FIG. 12B is an enlarged view of a portion CX3 of FIG. 12A;

FIG. 13A is a diagram for explaining a semiconductor memory device according to some embodiments;

FIG. 13B is an enlarged view of a portion CX4 of FIG. 13A;

FIG. 14A, FIG. 14B, FIG. 14C, FIG. 15A, FIG. 15B, FIG. 15C, FIG. 16A, FIG. 16B, FIG. 16C, FIG. 17A, FIG. 17B, FIG. 17C, FIG. 18, FIG. 19, FIG. 20A, FIG. 20B, FIG. 21A, FIG. 21B, FIG. 22A, FIG. 22B, FIG. 23A, and FIG. 23B are schematic views showing a method of manufacturing a semiconductor memory device according to some embodiments; and

FIG. 24 to FIG. 26 are schematic views showing a method of manufacturing a semiconductor memory device according to some embodiments.

### DETAILED DESCRIPTION OF THE EMBODIMENTS

Embodiments will now be described more fully with reference to the accompanying drawings. Like reference numerals in the accompanying drawings refer to like elements throughout, and duplicate descriptions thereof are omitted.

Throughout the specification, when a component is described as “including” a particular element or group of elements, it is to be understood that the component is formed of only the element or the group of elements, or the element or group of elements may be combined with additional elements to form the component, unless the context indicates otherwise. The term “consisting of,” on the other hand, indicates that a component is formed only of the element(s) listed.

As used herein, components described as being “electrically connected” are configured such that an electrical signal can be transferred from one component to the other (although such electrical signal may be attenuated in strength as it is transferred and may be selectively transferred). Moreover, components that are “directly electrically connected” form a common electrical node through electrical connections by one or more conductors, such as, for example, wires, pads, internal electrical lines, through vias, etc. As such, directly electrically connected components do not include components electrically connected through active elements, such as transistors or diodes.

Spatially relative terms, such as “beneath,” “below,” “lower,” “above,” “upper,” “top,” “bottom,” and the like, may be used herein for ease of description to describe one element's or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations) and the spatially relative descriptors used herein interpreted accordingly.

It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element (or using any form of the word “contact”), there are no intervening elements present at the point of contact.

Items described in the singular herein may be provided in plural, as can be seen, for example, in the drawings. Thus, the description of a single item that is provided in plural should be understood to be applicable to the remaining plurality of items unless context indicates otherwise.

Herein, a horizontal direction may include a first horizontal direction (X direction) and a second horizontal direction (Y direction) that cross (e.g., are perpendicular to or intersect) each other. A direction crossing (e.g., perpendicular to or intersecting) both the first horizontal direction (X direction) and the second horizontal direction (Y direction) may be referred to as a vertical direction (Z direction). Herein, a vertical level may be referred to as a height level of any component in the vertical direction (Z direction).

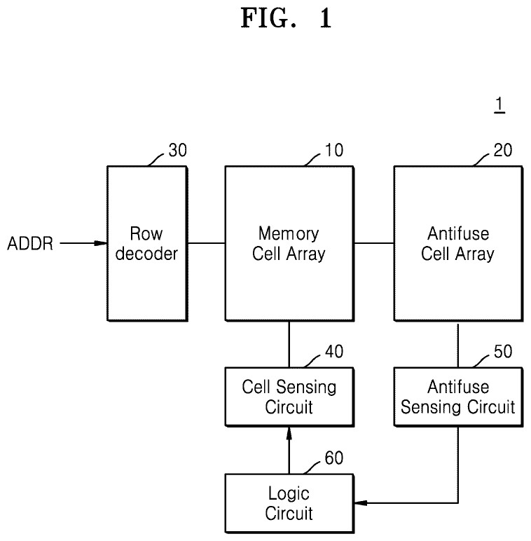

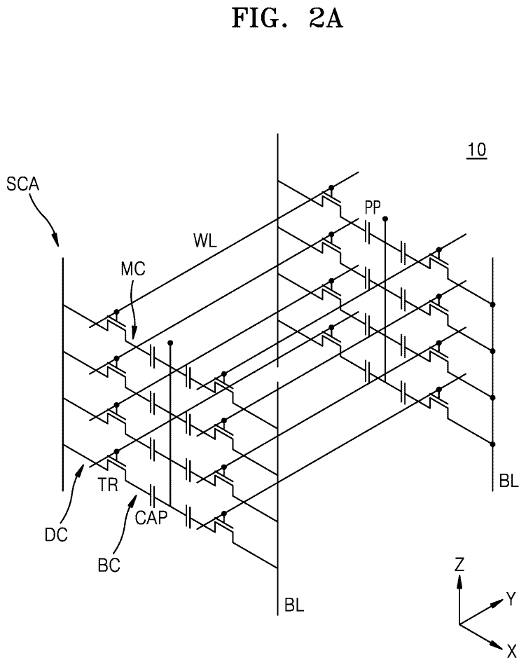

FIG. 1 is a block diagram schematically showing a semiconductor memory device 1 according to some embodiments.

Referring to FIG. 1, the semiconductor memory device 1 may include a memory cell array 10, an antifuse cell array 20, a row decoder 30, a cell sensing circuit 40, an antifuse sensing circuit 50, and a logic circuit 60.

The memory cell array 10 may include a plurality of word lines and a plurality of memory cells connected to the plurality of word lines. The plurality of memory cells may be arranged in columns and rows. The plurality of memory cells may include dynamic random-access memory (DRAM) devices. The plurality of word lines of the memory cell array 10 may be connected to the row decoder 30.

The antifuse cell array 20 may include a plurality of antifuse cells connected between a plurality of antifuse word lines and a plurality of antifuse bit lines. The plurality of antifuse cells may store information about fail cells included in the memory cell array 10. For example, address data of a fail cell may be electrically programmed to an antifuse cell.

The row decoder 30 may select a word line by decoding an address ADDR received as an input (e.g., from outside the semiconductor memory device), and data may be read from an antifuse cell and/or a memory cell connected to the selected word line.

The cell sensing circuit 40 may select some bit lines among bit lines of the memory cell array 10 in response to a control signal provided from the logic circuit 60.

The antifuse sensing circuit 50 may sense fail cell information stored in antifuse cells of the antifuse cell array 20, which are connected to the selected word line, and may amplify the fail cell information. The antifuse sensing circuit 50 may provide, to the logic circuit 60, a fail column address read from the antifuse cell array 20.

The logic circuit 60 may determine whether the address ADDR received as an input (e.g., from outside the semiconductor memory device) matches an address of a fail cell, based on the address of the fail cell stored in the plurality of antifuse cells. When the address ADDR received as an input (e.g., from outside the semiconductor memory device) matches the address of the fail cell, the logic circuit 60 may read fail cell information from an antifuse cell corresponding to the fail cell and provide the fail cell information as an output.

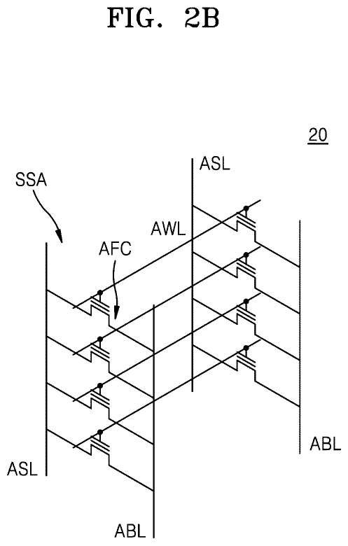

FIG. 2A is a circuit diagram showing the memory cell array 10 shown in FIG. 1.

FIG. 2B is a circuit diagram showing the antifuse cell array 20 shown in FIG. 1.

Referring to FIG. 2A, the memory cell array 10 may include a plurality of sub-cell arrays SCA (e.g., subsets of the memory cell array 10). The plurality of sub-cell arrays SCA may be arranged apart from each other in the second horizontal direction (Y direction).

The sub-cell array SCA may include a plurality of bit lines BL, a plurality of word lines WL, and a plurality of memory cells MC. Each of the plurality of memory cells MC may include one cell transistor TR and one cell capacitor CAP connected thereto. For example, each of the plurality of memory cells MC may have a one transistor-one capacitor (1T1C) structure.

The plurality of word lines WL may extend in the second horizontal direction (Y direction) and may be arranged apart from each other in the first horizontal direction (X direction) and the vertical direction (Z direction). The plurality of bit lines BL may extend in the vertical direction (Z direction) and may be arranged apart from each other in each of the first horizontal direction (X direction) and the second horizontal direction (Y direction). One cell transistor TR may be arranged between one word line WL and one bit line BL (e.g., between each pair of adjacent word lines and each pair of adjacent bit lines).

Agate of a cell transistor TR may be connected to the word line WL, and a source electrode of the cell transistor TR may be connected to the bit line BL via a first contact DC. The cell transistor TR may be connected to a cell capacitor CAP via a second contact BC. A drain electrode of the cell transistor TR may be connected to a first electrode of the cell capacitor CAP via the second contact BC, and a second electrode of the cell capacitor CAP may be connected to a plate electrode PP.

In one sub-cell array SCA, a plurality of cell transistors TR may be arranged at positions that overlap each other in the vertical direction (e.g., their projections along the Z direction may coincide). In one sub-cell array SCA, a plurality of cell capacitors CAP may be arranged at positions that overlap each other in the vertical direction (Z direction). One cell transistor TR and one cell capacitor CAP may be arranged in series at the same vertical level, and a plurality of memory cells MC, each including one cell transistor TR and one cell capacitor CAP, may be stacked in the vertical direction (Z direction). The storage capacity of the sub-cell array SCA may vary depending on the number, or number of layers, of memory cells MC (for example, the number, or number of layers, of cell capacitors CAP) stacked in the vertical direction (Z direction).

Referring to FIG. 2B, the antifuse cell array 20 may include a plurality of antifuse sub-cell arrays SSA. The plurality of antifuse sub-cell arrays SSA may be arranged apart from each other in the second horizontal direction (Y direction).

The antifuse sub-cell array SSA may include a plurality of antifuse bit lines ABL, a plurality of antifuse word lines AWL, a plurality of antifuse source lines ASL, and a plurality of antifuse cells AFC.

The plurality of antifuse cells AFC may be connected between the plurality of antifuse word lines AWL and the plurality of antifuse bit lines ABL. In some embodiments, the plurality of antifuse cells AFC may include charge trapping type non-volatile memory devices. A gate of the antifuse cell AFC may be connected to the antifuse word line AWL, a source of the antifuse cell AFC may be connected to the antifuse source line ASL, and a drain of the antifuse cell AFC may be connected to the antifuse bit line ABL.

In one antifuse sub-cell array SSA, the plurality of antifuse cells AFC may be arranged at positions that overlap each other in the vertical direction (Z direction). In some embodiments, the plurality of antifuse cells AFC may be formed together within at least a portion of a process for forming the cell transistor TR in the memory cell array 10. In some embodiments, the number (for example, the number of layers) of the plurality of antifuse cells AFC stacked in the vertical direction (Z direction) may be equal to the number (for example, the number of layers) of cell capacitors CAP stacked in the vertical direction (Z direction). In some embodiments, the number (for example, the number of layers) of the plurality of antifuse cells AFC stacked in the vertical direction (Z direction) may be less than the number (for example, the number of layers) of cell capacitors CAP stacked in the vertical direction (Z direction).

In some embodiments, the plurality of antifuse cells AFC may include charge trapping type non-volatile memory devices, and the plurality of antifuse cells AFC may have a relatively high first threshold voltage in a programmed state (for example, after a program operation) and may have a second threshold voltage lower than the first threshold voltage in an unprogrammed state.

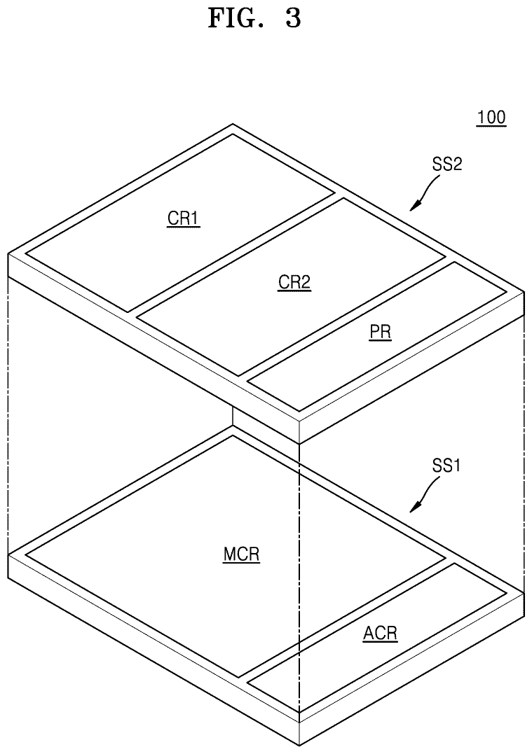

FIG. 3 is a perspective view showing a semiconductor memory device 100 according to some embodiments.

Referring to FIG. 3, the semiconductor memory device 100 may have a structure in which a first stack structure SS1 and a second stack structure SS2 are stacked in the vertical direction. For example, the first stack structure SS1 and the second stack structure SS2 may be arranged at different vertical levels. For convenience of understanding, FIG. 3 shows that the first stack structure SS1 and the second stack structure SS2 are separated, but the semiconductor memory device 100 may have a structure in which a bottom surface of the second stack structure SS2 is attached to a top surface of the first stack structure SS1.

The first stack structure SS1 may include a memory cell region MCR and an antifuse array region ACR. The memory cell region MCR may be a region in which the memory cell array 10 described with reference to FIGS. 1 and 2A is arranged. For example, bit lines, word lines, and memory cells may be arranged in the memory cell region MCR. The antifuse array region ACR may be a region in which the antifuse cell array 20 described with reference to FIGS. 1 and 2B is arranged. The antifuse array region ACR may be arranged on one side of the memory cell region MCR. For example, antifuse bit lines, antifuse word lines, and antifuse cells may be arranged in the antifuse array region ACR.

The second stack structure SS2 may include a first core region CR1, a second core region CR2, and a peripheral circuit region PR. The first core region CR1 and the second core region CR2 may be arranged at positions that vertically overlap the memory cell region MCR, and may include core circuits electrically connected to the memory cell region MCR. In some embodiments, the first core region CR1 may include sense amplifiers, and the sense amplifiers may be electrically connected to the bit lines included in the first stack structure SS1. In some embodiments, the second core region CR2 may include sub-word line drivers, and the sub-word line drivers may be electrically connected to the word lines included in the first stack structure SS1.

The peripheral circuit region PR may be arranged at a position that vertically overlaps the antifuse array region ACR. The peripheral circuit region PR may include a control signal generation circuit for controlling a sub-word line driver, a control signal generation circuit for controlling a sense amplifier, and an antifuse cell sensing circuit for controlling an antifuse cell array arranged in the antifuse array region ACR. In addition, the peripheral circuit region PR may further include a voltage generator that provides an operating voltage to a sense amplifier, a sub-word line driver, an antifuse cell sensing circuit, etc.

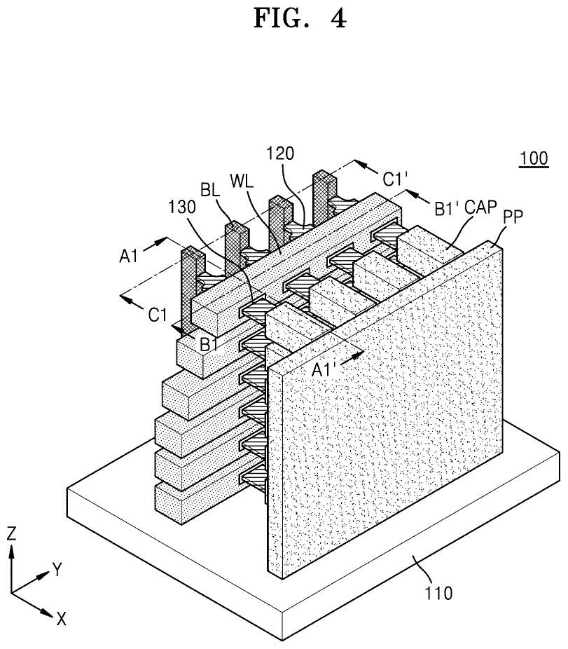

FIG. 4 is a schematic perspective view showing a memory cell region of the semiconductor memory device 100 according to some embodiments.

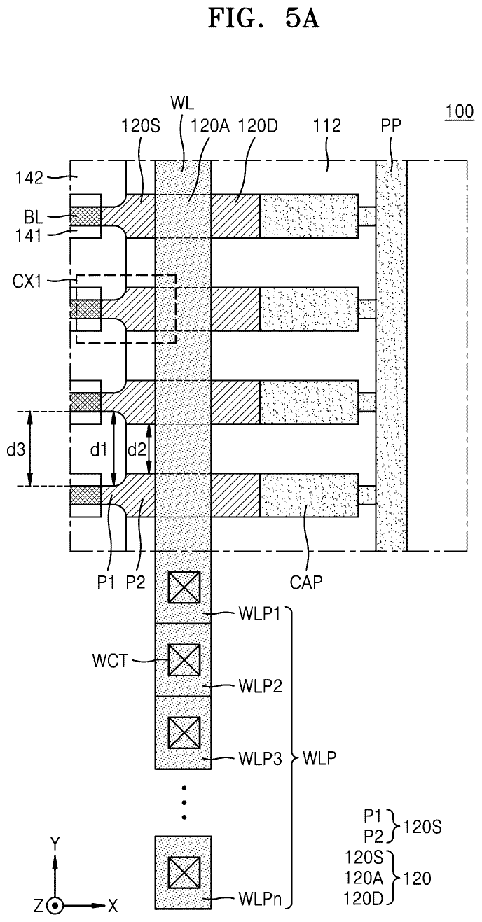

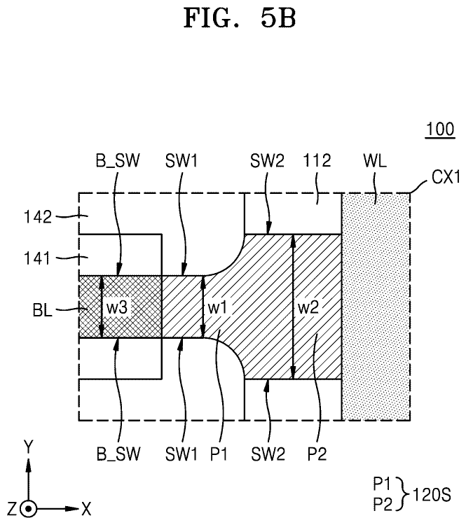

FIG. 5A is a layout diagram showing a memory cell region of the semiconductor memory device 100 according to some embodiments.

FIG. 5B is an enlarged view of a portion CX1 of FIG. 5A.

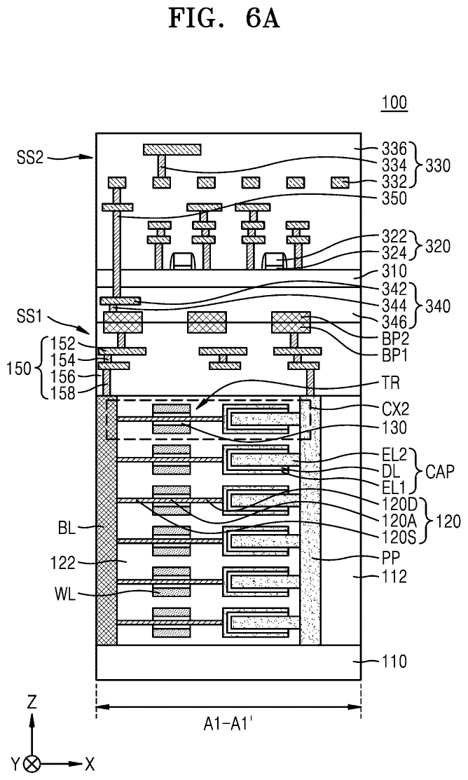

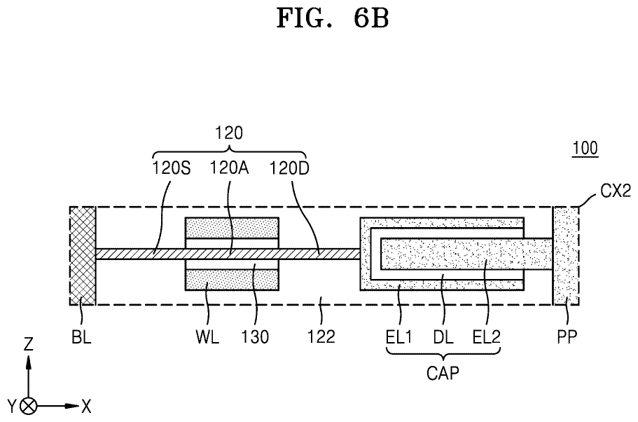

FIG. 6A is a cross-sectional view taken along a line A1-A1′ of FIG. 4.

FIG. 6B is an enlarged view of a portion CX2 of FIG. 6A.

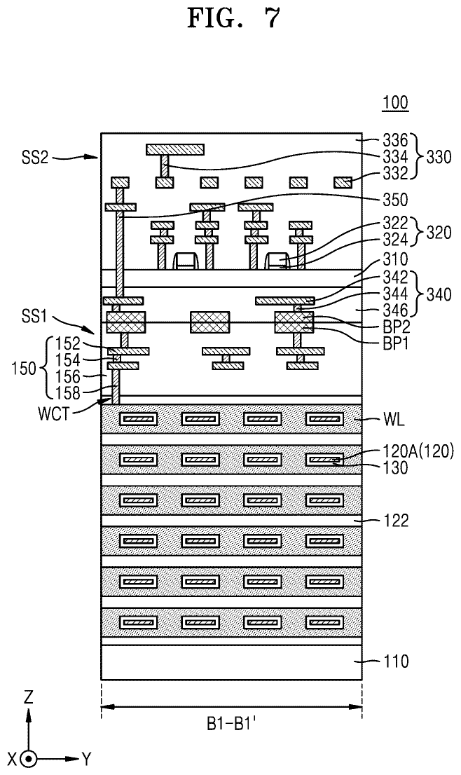

FIG. 7 is a cross-sectional view taken along a line B1-B1′ of FIG. 4.

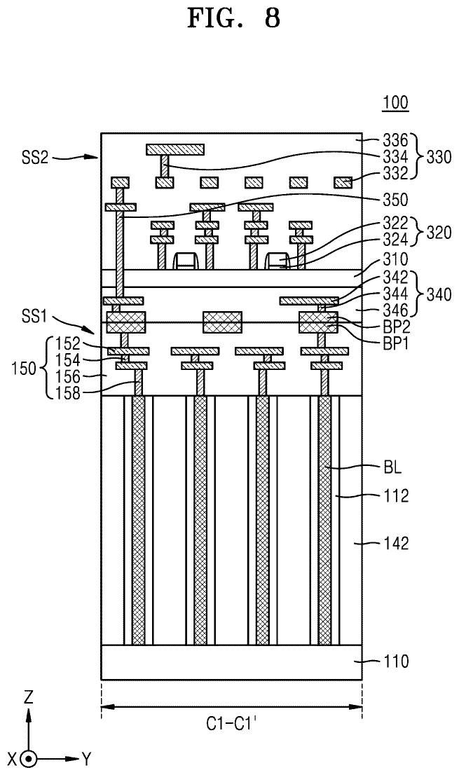

FIG. 8 is a cross-sectional view taken along a line C1-C1′ of FIG. 4.

Referring to FIGS. 4, 5A, 5B, 6A, 6B, 7, and 8, the semiconductor memory device 100 may include the first stack structure SS1 and the second stack structure SS2, and the second stack structure SS2 may be bonded onto the first stack structure SS1 by first and second bonding pads BP1 and BP2.

The first stack structure SS1 may include the memory cell region MCR and the antifuse array region ACR (see FIG. 3), but for convenience, only the memory cell region MCR is shown. In some embodiments, the first stack structure SS1 may include a first substrate 110, a plurality of semiconductor patterns 120 arranged on the first substrate 110, a plurality of bit lines BL, a plurality of word lines WL, and a plurality of cell capacitors CAP.

In some embodiments, the first substrate 110 may include Si, Ge, or SiGe. In some embodiments, the first substrate 110 may include a silicon-on-insulator (SOI) substrate or a germanium-on-insulator (GeOI) substrate.

In some embodiments, the plurality of semiconductor patterns 120 arranged on the first substrate 110 may extend in the first horizontal direction (X direction) and may be arranged apart from each other in the vertical direction (Z direction).

In some embodiments, the plurality of semiconductor patterns 120 may include, for example, an undoped semiconductor material or a doped semiconductor material. In some embodiments, the plurality of semiconductor patterns 120 may include polysilicon. In some embodiments, the plurality of semiconductor patterns 120 may include amorphous metal oxide, polycrystalline metal oxide, or a combination of amorphous metal oxide and polycrystalline metal oxide, and for example, may include at least one of In—Ga-based oxide (IGO), In—Zn-based oxide (IZO), or In—Ga—Zn-based oxide (IGZO). In some embodiments, the plurality of semiconductor patterns 120 may include a 2D material semiconductor, and for example, the 2D material semiconductor may include MoS2, WSe2, graphene, carbon nano tube, or a combination thereof.

In some embodiments, the plurality of semiconductor patterns 120 may have a line shape or a bar shape, which extends in the first horizontal direction (X direction). In some embodiments, each of the plurality of semiconductor patterns 120 may include a channel region 120A, and a first impurity region 120S and a second impurity region 120D arranged in the first horizontal direction (X direction) with the channel region 120A therebetween. The first impurity region 120S may be connected to the bit line BL, and the second impurity region 120D may be connected to the cell capacitor CAP. An ohmic metal layer including metal silicide may be further formed between the first impurity region 120S and the bit line BL and between the second impurity region 120D and the cell capacitor CAP.

As shown in FIGS. 5A and 5B, in some embodiments, the first impurity region 120S of the semiconductor pattern 120 may have a horizontal width in the second horizontal direction (Y direction), which gradually varies in the first horizontal direction (X direction). The first impurity region 120S may include a first portion P1 that is in contact with the bit line BL and a second portion P2 spaced apart from the bit line BL with the first portion P1 therebetween.

In some embodiments, the first portion P1 may have a first horizontal width w1 in the second horizontal direction (Y direction), and the second portion P2 may have a second horizontal width w2 in the second horizontal direction (Y direction). The first horizontal width w1 of the first portion P1 may continuously vary in the first horizontal direction (X direction). For example, the first horizontal width w1 of the first portion P1 may increase in a direction toward the second portion P2, as shown. The second horizontal width w2 of the second portion P2 may not continuously vary in the first horizontal direction (X direction) and may be substantially constant. The second horizontal width w2 of the second portion P2 may be greater than a minimum value of the first horizontal width w1 of the first portion P1.

In some embodiments, the bit line BL may have a third horizontal width w3 in the second horizontal direction (Y direction). The third horizontal width w3 of the bit line BL may not continuously vary in the first horizontal direction (X direction) and may be substantially constant. The third horizontal width w3 of the bit line BL may be less than the second horizontal width w2 of the second portion P2. The third horizontal width w3 of the bit line BL may be equal to, less than, or greater than the minimum value of the first horizontal width w1 of the first portion P1. For example, as shown in FIGS. 5A and 5B, the third horizontal width w3 of bit line BL may be substantially equal to the minimum value of the first horizontal width w1 of the first portion P1, which in turn may be less than the second horizontal width w2 of the second portion P2.

For example, the first horizontal width w1 of the first portion P1 may vary between about 20 nanometers and about 50 nanometers, the second horizontal width w2 of the second portion P2 may be a constant value between about 50 nanometers and about 90 nanometers, and the third horizontal width w3 of the bit line BL may be a constant value between about 20 nanometers and about 30 nanometers. For example, the second horizontal width w2 may be between about 2.5 times and about 4 times the third horizontal width w3.

In some embodiments, a separation distance in the second horizontal direction (Y direction) between first portions P1 of first impurity regions 120S of a pair of adjacent semiconductor patterns 120 may be defined as a first distance d1. A separation distance in the second horizontal direction (Y direction) between second portions P2 of the first impurity regions 120S of the pair of adjacent semiconductor patterns 120 may be defined as a second distance d2. The first distance d1 may continuously vary in the first horizontal direction (X direction). For example, the first distance d1 may decrease in a direction toward the word line WL. The second distance d2 may not continuously vary in the first horizontal direction (X direction) and may be substantially constant. The second distance d2 may be less than a maximum value of the first distance d1.

In some embodiments, a spacing, or separation distance between a pair of adjacent bit lines BL, may be defined as a third distance d3. The third distance d3 may not continuously vary in the first horizontal direction (X direction) and may be substantially constant. The third distance d3 may be greater than the second distance d2. In some examples, the third distance d3 may be substantially equal to the maximum value of the first distance d1.

For example, the first distance d1 may vary between about 50 nanometers and about 80 nanometers, the second distance d2 may be a constant value between about 10 nanometers and about 50 nanometers, and the third distance d3 may be a constant value between about 70 nanometers and about 80 nanometers.

Meanwhile, the second impurity region 120D of the semiconductor pattern 120 may have a horizontal width in the second horizontal direction (Y direction), which is maintained to be constant in the first horizontal direction (X direction). In some embodiments, the horizontal width of the second impurity region 120D in the second horizontal direction (Y direction) may be substantially equal to the horizontal width of the cell capacitor CAP in the second horizontal direction (Y direction).

In some embodiments, the first impurity region 120S of the semiconductor pattern 120 may have a pair of side walls opposite each other in the second horizontal direction (Y direction), and a portion of the pair of side walls of the first impurity region 120S may have a curvature. For example, a pair of first side walls SW1 of the first portion P1 of the first impurity region 120S, which are opposite to each other, may have a curvature, and a pair of second side walls SW2 of the second portion P2, which are opposite to each other, may have a flat shape. For example, in a direction toward the bit line BL, each of the pair of first side walls SW1 of the first portion P1 of the first impurity region 120S, which are opposite to each other, may have a shape that is rounded so that the pair of first side walls SW1 are closer in a direction in which the pair of first side walls SW1 of the first portion P1 of the first impurity region 120S are opposite to each other. In other words, the pair of first side walls SW1 of the first portion P1 of the first impurity region 120S, which are opposite to each other, may have a concave shape. For example, the pair of first side walls SW1 of the first portion P1 of the first impurity region 120S, which are opposite to each other, may have an elliptical arc shape in the layout. The pair of second side walls SW2 of the second portion P2, which are opposite to each other, may extend to be substantially parallel to each other. In some embodiments, a pair of third side walls B_SW of the bit line BL, which are opposite to each other, may extend to be substantially parallel to each other.

As shown in FIGS. 4 and 5A, the word line WL may extend in the second horizontal direction (Y direction) to cross (e.g., intersect) the first horizontal direction (X direction), which is a direction in which the semiconductor pattern 120 extends. A word line pad WLP may be arranged at an end of the word line WL. A plurality of word line pads WLP may be arranged in order in the second horizontal direction (Y direction), as shown in FIG. 5A, and the plurality of word line pads WLP may be arranged to have a step shape in the second horizontal direction (Y direction).

In some embodiments, the plurality of word line pads (e.g., WLP1 through WLPn) may be arranged in order in the second horizontal direction (Y direction), and an n^{th} word line pad WLPn connected to an n^{th} word line WL from the top may be arranged in the second horizontal direction (Y direction). For example, a first word line pad WLP1 may be connected to a word line WL arranged at the top of the plurality of word lines WL, a second word line pad WLP2 may be connected to a word line WL arranged under the word line WL arranged at the top, and a third word line WLP3 may be connected to a word line WL arranged under the two word lines WL. These two word lines WL may be respectively arranged at the top and arranged under the word line WL arranged at the top. In such an example, the plurality of word line pads WLP may be arranged in order in the second horizontal direction (Y direction), with an n^{th} word line pad WLPn connected to an n^{th} word line WL from the top may be arranged in the second horizontal direction (Y direction).

A word line contact WCT may be arranged on an upper surface of each of the plurality of word line pads WLP, and the word line WL may be electrically connected to an upper wiring structure 150 (of FIG. 7) by the word line contact WCT.

In some embodiments, the plurality of word lines WL may include at least one of a doped semiconductor material (doped silicon, doped germanium, etc.), a conductive metal nitride (titanium nitride, tantalum nitride, etc.), a metal (tungsten, titanium, tantalum, etc.), and a metal-semiconductor compound (tungsten silicide, cobalt silicide, titanium silicide, etc.).

In some embodiments, a gate insulating layer 130 may be arranged between the word line WL and the semiconductor pattern 120. The gate insulating layer 130 may include at least one selected from a high-k dielectric material and a ferroelectric material, each having a higher dielectric constant than silicon oxide. In some embodiments, the gate insulating layer 130 may include at least one material selected from hafnium oxide (HfO), hafnium silicate (HfSiO), hafnium oxynitride (HfON), hafnium silicon oxynitride (HfSiON), lanthanum oxide (LaO), lanthanum aluminum oxide (LaAlO), zirconium oxide (ZrO), zirconium silicate (ZrSiO), zirconium oxynitride (ZrON), zirconium silicon oxynitride (ZrSiON), tantalum oxide (TaO), titanium oxide (TiO), barium strontium titanium oxide (BaSrTiO), barium titanium oxide (BaTiO), lead zirconate titanate (PZT), strontium bismuth tantalate (STB), bismuth iron oxide (BFO), strontium titanium oxide (SrTiO), yttrium oxide (YO), aluminum oxide (AlO), or lead scandium tantalum oxide (PbScTaO).

In some embodiments, the plurality of bit lines BL may extend in the vertical direction (Z direction) on the first substrate 110 and may be arranged apart from each other in the second horizontal direction (Y direction). In an example, the plurality of bit lines BL may be located at the same location along the first horizontal direction (X direction). The plurality of bit lines BL may be formed from any one of a doped semiconductor material, a conductive metal nitride, a metal, and a metal-semiconductor compound.

In some embodiments, each cell capacitor of the plurality of cell capacitors CAP may include a first electrode EL1, a capacitor dielectric layer DL, and a second electrode EL2. The first electrodes EL1 may extend in the first horizontal direction (X direction) and may be arranged apart in the vertical direction (Z direction). The first electrode EL1 may have an internal space (e.g., a filled groove or filled cavity; not shown) extending in the first horizontal direction (X direction), and the internal space (e.g., filled groove or filled cavity) may be occupied by the capacitor dielectric layer DL and the second electrode EL2. For example, as shown in FIG. 6A, the first electrode EL1 may have a cup shape rotated by 90 degrees.

In some embodiments, the capacitor dielectric layer DL may include at least one selected from a high-k dielectric material and a ferroelectric material, each having a higher dielectric constant than silicon oxide. In some embodiments, the capacitor dielectric layer DL may include at least one material selected from hafnium oxide (HfO), hafnium silicate (HfSiO), hafnium oxynitride (HfON), hafnium silicon oxynitride (HfSiON), lanthanum oxide (LaO), lanthanum aluminum oxide (LaAlO), zirconium oxide (ZrO), zirconium silicate (ZrSiO), zirconium oxynitride (ZrON), zirconium silicon oxynitride (ZrSiON), tantalum oxide (TaO), titanium oxide (TiO), barium strontium titanium oxide (BaSrTiO), barium titanium oxide (BaTiO), lead zirconate titanate (PZT), strontium bismuth tantalate (STB), bismuth iron oxide (BFO), strontium titanium oxide (SrTiO), yttrium oxide (YO), aluminum oxide (AlO), or lead scandium tantalum oxide (PbScTaO).

In some embodiments, the second electrode EL2 may occupy the internal space of the first electrode EL1, and the capacitor dielectric layer DL may be arranged between the internal space of the first electrode EL1 and the second electrode EL2. For example, as shown in FIG. 6A, the capacitor dielectric layer DL and second electrode EL2 may be layered inside the cup shape of the first electrode EL1.

In some embodiments, the first electrode EL1 and the second electrode EL2 may include a doped semiconductor material, a conductive metal nitride such as titanium nitride, tantalum nitride, niobium nitride, or tungsten nitride, a metal of ruthenium, iridium, titanium, or tantalum, and a conductive metal oxide such as iridium oxide or niobium oxide.

In some embodiments, the plate electrode PP may be arranged on one side of the cell capacitor CAP and extend in the vertical direction (Z direction) and the second horizontal direction (Y direction). The second electrode EL2 of the cell capacitor CAP may be electrically connected to the plate electrode PP, and for example, a plurality of second electrodes EL2 arranged apart from each other in the vertical direction (Z direction) and a plurality of second electrodes EL2 arranged apart from each other in the second horizontal direction (Y direction) may be commonly connected to the plate electrode PP.

In some embodiments, a filling insulating layer 112 may be arranged between two semiconductor patterns 120 that are adjacent to each other in the second horizontal direction (Y direction). For example, the filling insulating layer 112 may be arranged between second portions P2 of first impurity regions 120S of two semiconductor patterns 120 that are adjacent to each other in the second horizontal direction (Y direction). The filling insulating layer 112 may be in contact with the second portion P2 of the first impurity region 120S of each of the plurality of semiconductor patterns 120. In addition, the filling insulating layer 112 may be arranged between cell capacitors CAP that are adjacent to each other in the second horizontal direction (Y direction).

In some embodiments, a mold insulating layer 122 may be arranged between two semiconductor patterns 120 that are adjacent to each other in the vertical direction (Z direction), between two word lines WL that are adjacent to each other in the vertical direction (Z direction), and between two cell capacitors CAP that are adjacent to each other in the vertical direction (Z direction). In addition, in some embodiments, the mold insulating layer 122 may also be arranged between two bit lines BL that are adjacent to each other in the vertical direction (Z direction).

In some embodiments, the filling insulating layer 112 and the mold insulating layer 122 may include silicon oxide, silicon oxynitride, silicon nitride, carbon-containing silicon oxide, carbon-containing silicon oxynitride, carbon-containing silicon nitride, or a combination thereof. In some embodiments, the mold insulating layer 122 may include a plurality of insulating layers.

In some embodiments, an inner insulating spacer 141 may be arranged between two bit lines BL that are adjacent to each other in the second horizontal direction (Y direction), to cover side walls of the two bit lines BL in the second horizontal direction (Y direction). In some embodiments, an outer insulating spacer 142 may be arranged between two bit lines BL that are adjacent to each other in the second horizontal direction (Y direction), to include the inner insulating spacer 141. Herein, the inner insulating spacer 141 and the outer insulating spacer 142 may be collectively referred to as an “insulating spacer”. The outer insulating spacer 142 may extend between first portions P1 of first impurity regions 120S of two semiconductor patterns that are adjacent to each other in the second horizontal direction (Y direction). The outer insulating spacer 142 may be in contact with the first portion P1 of the first impurity region 120S of each of the plurality of semiconductor patterns 120.

In some examples, the width w3 of the bit lines BL in the second horizontal direction (Y direction) may be less than the spacing d3 between adjacent bit lines BL. For example, the width w3 plus the width of the inner insulating spacer 141 in the second horizontal direction (Y direction) on both sides of bit line BL may substantially or approximately equal the second horizontal width w2 in the second horizontal direction (Y direction), as illustrated in FIG. 5B. In a second example, the spacing d3 between adjacent bit lines BL may substantially or approximately equal the width of the outer insulating spacer 142 in the second horizontal direction (Y direction) plus the width of the inner insulating spacer 141 in the second horizontal direction (Y direction) on both sides of bit line BL, as illustrated in FIG. 5A.

It is shown that the insulating spacer arranged between two bit lines BL that are adjacent to each other in the second horizontal direction (Y direction) includes two layers that are the inner insulating spacer 141 and the outer insulating spacer 142, but may include a single layer or at least three layers depending on a process.

In some embodiments, the insulating spacer may include silicon oxide, silicon oxynitride, silicon nitride, carbon-containing silicon oxide, carbon-containing silicon oxynitride, carbon-containing silicon nitride, or a combination thereof. In some embodiments, the insulating spacer may include an air gap. The term “air gap” used herein may be understood to include any cavity filled with any substantially inert gas or gaseous substance (including, but not limited to, air or other gases that may be present during the manufacturing process) or may comprise a gap forming a vacuum therein and devoid of solid material.

In some embodiments, the first stack structure SS1 may include the upper wiring structure 150. The upper wiring structure 150 may include a wiring layer 152, a via 154, and an interlayer insulating layer 156. The upper wiring structure 150 may further include a contact 158 electrically connected to the bit line BL, the word line WL, and the plate electrode PP. In addition, the first bonding pad BP1 that is coplanar with a top surface of the interlayer insulating layer 156 may be formed on the upper wiring structure 150.

In some embodiments, the second stack structure SS2 may include a second substrate 310, a peripheral circuit transistor 320 arranged on the second substrate 310, a front wiring structure 330 that covers the peripheral circuit transistor 320 on a top surface of the second substrate 310, and a rear wiring structure 340 arranged on a bottom surface of the second substrate 310. The front wiring structure 330 may include a wiring layer 332, a via 334, and an insulating layer 336, and the rear wiring structure 340 may include a wiring layer 342, a via 344, and a peripheral circuit insulating layer 346.

In some embodiments, the rear wiring structure 340 may include the second bonding pad BP2 that is coplanar with a bottom surface of the peripheral circuit insulating layer 346, and as the first bonding pad BP1 and the second bonding pad BP2 are connected to each other, the first stack structure SS1 and the second stack structure SS2 may be bonded to each other. In some embodiments, the first stack structure SS1 and the second stack structure SS2 may be attached using a copper-oxide hybrid bonding method. In some embodiments, the first bonding pad BP1 and the second bonding pad BP2 may include copper or a copper alloy. An interface between the interlayer insulating layer 156 of the upper wiring structure 150 and the peripheral circuit insulating layer 346 of the rear wiring structure 340 may extend in a flat manner and may be coplanar with an interface between the first bonding pad BP1 and the second bonding pad BP2.

In some embodiments, the peripheral circuit transistor 320 may include a gate electrode 322 and a gate insulating layer 324, which are arranged in an active region of the second substrate 310. In some embodiments, the peripheral circuit transistor 320 may include sense amplifiers, and the sense amplifiers may be electrically connected to the plurality of bit lines BL included in the first stack structure SS1. In addition, the peripheral circuit transistor 320 may include sub-word line drivers, and the sub-word line drivers may be electrically connected to the plurality of word lines WL included in the first stack structure SS1.

In some embodiments, the second stack structure SS2 may further include a through via 350 penetrating the second substrate 310. The wiring layer 332 included in the front wiring structure 330 may be electrically connected to the wiring layer 342 included in the rear wiring structure 340 by the through via 350. In addition, the wiring layer 342 included in the rear wiring structure 340 may be electrically connected to the wiring layer 152 included in the upper wiring structure 150 via the second bonding pad BP2 and the first bonding pad BP1.

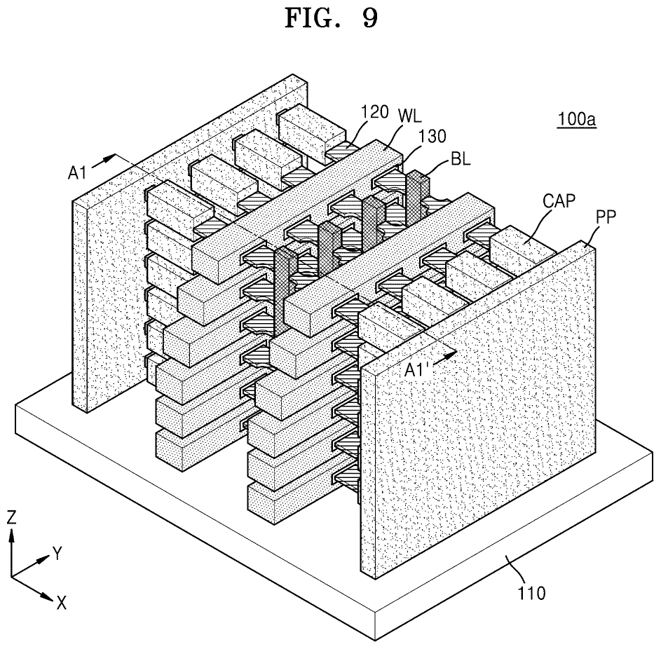

FIG. 9 is a schematic perspective view showing a memory cell region of a semiconductor memory device 100a according to some embodiments.

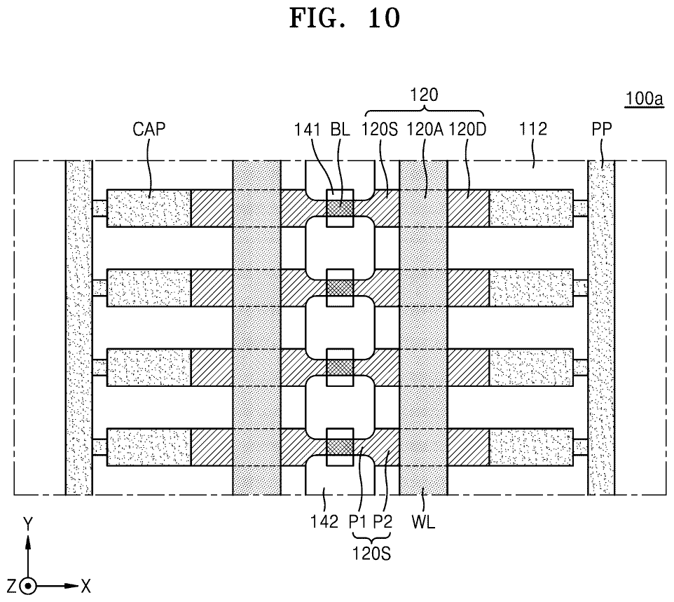

FIG. 10 is a layout diagram showing the memory cell region of the semiconductor memory device 100a according to some embodiments.

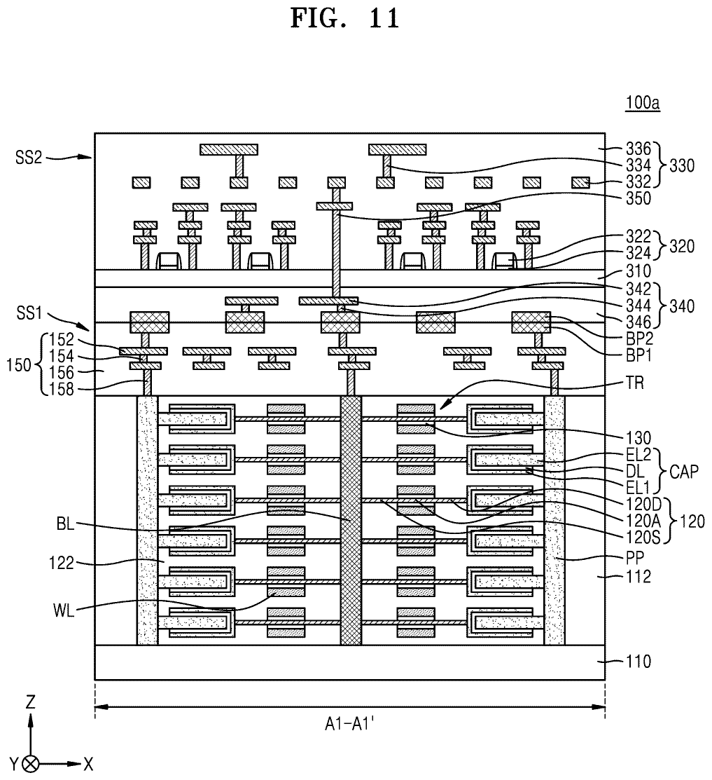

FIG. 11 is a cross-sectional view taken along a line A2-A2′ of FIG. 9.

The semiconductor memory device 100a shown in FIGS. 9, 10, and 11 may be formed to be generally similar to the semiconductor memory device 100 described above, and thus, hereinafter, only differences from the semiconductor memory device 100 are described in detail. In FIGS. 9, 10, and 11, the same reference numerals as those in FIGS. 4, 5A, 5B, 6A, 6B, 7, and 8 denote same components, and detailed descriptions thereof are omitted.

The semiconductor memory device 100a may include the first stack structure SS1 and the second stack structure SS2, and the second stack structure SS2 may be bonded onto the first stack structure SS1 by the first and second bonding pads BP1 and BP2. In some embodiments, the first stack structure SS1 may include the first substrate 110, the plurality of semiconductor patterns 120 arranged on the first substrate 110, the plurality of bit lines BL, the plurality of word lines WL, the plurality of cell capacitors CAP, and the upper wiring structure 150. In some embodiments, the plurality of semiconductor patterns 120, the plurality of word lines WL, and the plurality of cell capacitors CAP may be formed in the first horizontal direction (X direction) to be mirror symmetrical about the plurality of bit lines BL. For example, the semiconductor memory device 100a may include the semiconductor memory device 100 of FIGS. 1-8, as well as the reflections of these elements about the plurality of bit lines BL.

In some embodiments, the plurality of word lines WL may be spaced apart from each other with the plurality of bit lines BL therebetween in the first horizontal direction (X direction). For example, a first group of word lines and a second group of word lines (e.g., the reflections of the first group of word lines) among the plurality of word lines WL may be spaced apart from each other with the plurality of bit lines BL therebetween in the first horizontal direction (X direction). At this time, a plurality of word lines of the first group may overlap each other in the vertical direction (Z direction), and a plurality of word lines of the second group may overlap each other in the vertical direction (Z direction). The plurality of bit lines BL may be arranged between the plurality of word lines WL spaced apart from each other in the first horizontal direction (X direction). The plurality of cell capacitors CAP may be spaced apart from the plurality of bit lines BL with the plurality of word lines WL therebetween in the first horizontal direction (X direction).

In some embodiments, the second stack structure SS2 may include the second substrate 310, the peripheral circuit transistor 320 arranged on the second substrate 310, the front wiring structure 330 that covers the peripheral circuit transistor 320 on the top surface of the second substrate 310, and the rear wiring structure 340 arranged on the bottom surface of the second substrate 310.

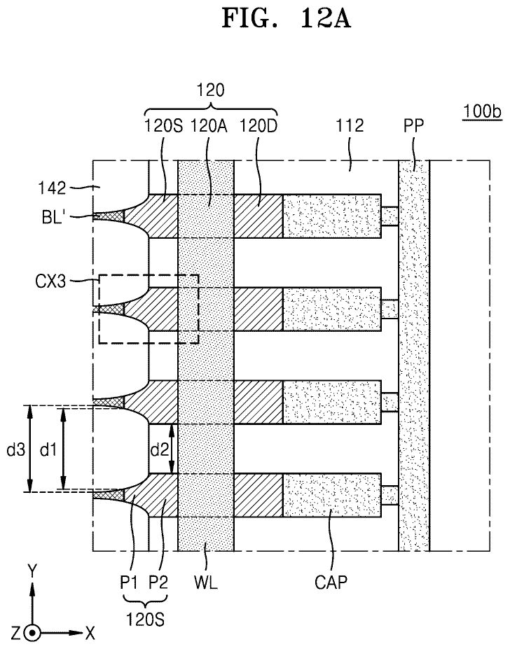

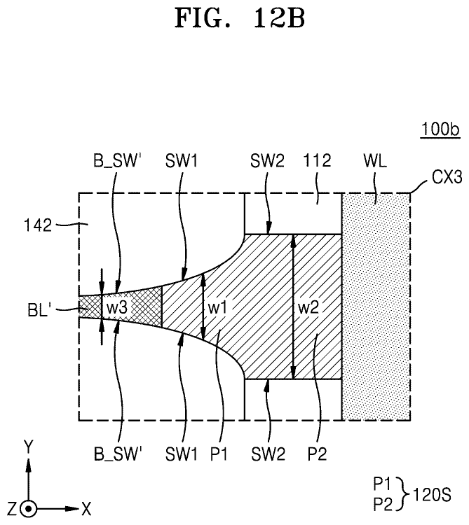

FIG. 12A is a diagram for explaining a semiconductor memory device 100b according to some embodiments.

FIG. 12A is a diagram schematically showing a portion of the semiconductor memory device 100b corresponding to a portion of the semiconductor memory device 100 shown in FIG. 5A.

FIG. 12B is an enlarged view of a portion CX3 of FIG. 12A.

The semiconductor memory device 100b shown in FIGS. 12A and 12B may be formed to be generally similar to the semiconductor memory device 100 described above, and thus, hereinafter, differences from the semiconductor memory device 100 are described in detail. In FIGS. 12A and 12B, the same reference numerals as those in FIGS. 4, 5A, 5B, 6A, 6B, 7, and 8 denote same components, and detailed descriptions thereof are omitted.

Referring to FIGS. 12A and 12B, in some embodiments, the first impurity region 120S of the semiconductor pattern 120 may have a horizontal width in the second horizontal direction (Y direction), which gradually varies in the first horizontal direction (X direction). The first impurity region 120S may include the first portion P1 that is in contact with a bit line BL′ and the second portion P2 spaced apart from the bit line BL′ with the first portion P1 therebetween.

In some embodiments, the first portion P1 may have the first horizontal width w1 in the second horizontal direction (Y direction), and the second portion P2 may have the second horizontal width w2 in the second horizontal direction (Y direction). The first horizontal width w1 of the first portion P1 may continuously vary in the first horizontal direction (X direction). For example, the first horizontal width w1 of the first portion P1 may increase in a direction toward the second portion P2. The second horizontal width w2 of the second portion P2 may not continuously vary in the first horizontal direction (X direction) and may be substantially constant. The second horizontal width w2 of the second portion P2 may be greater than a minimum value of the first horizontal width w1 of the first portion P1. At the interface between the first portion P1 and the second portion P2, the first horizontal width w1 may reach its maximum value, e.g. equal to the second horizontal width w2.

In some embodiments, the bit line BL′ may have the third horizontal width w3 in the second horizontal direction (Y direction). Unlike the substantially constant width w3 of the bit lines BL of the semiconductor memory devices 100 and 100a (e.g., in FIG. 5B), the third horizontal width w3 of the bit line BL′ may continuously vary in the first horizontal direction (X direction). A maximum value of the third horizontal width w3 of the bit line BL′ may be equal to the minimum value of the first horizontal width w1 of the first portion P1 and may be less than the second horizontal width w2 of the second portion P2.

In some embodiments, a separation distance in the second horizontal direction (Y direction) between first portions P1 of first impurity regions 120S of a pair of semiconductor patterns 120 may be defined as the first distance d1, and a separation distance between second portions P2 of the first impurity regions 120S of the pair of semiconductor patterns 120 may be defined as the second distance d2. The first distance d1 may continuously vary in the first horizontal direction (X direction) as the first horizontal width w1 of the first portion P1 varies. For example, the first distance d1 may decrease in a direction toward a word line WL. The second distance d2 may not continuously vary in the first horizontal direction (X direction) and may be substantially constant. The second distance d2 may be less than a maximum value of the first distance d1.

In some embodiments, a separation distance in the second horizontal direction (Y direction) between a pair of adjacent bit lines BL′ may be defined as the third distance d3. The third distance d3 may continuously vary in the first horizontal direction (X direction). The third distance d3 may be equal to or greater than the maximum value of the first distance d1 and may be greater than the second distance d2.

In some embodiments, the first impurity region 120S of the semiconductor pattern 120 may have a pair of side walls opposite to each other in the second horizontal direction (Y direction), and a portion of the pair of side walls of the first impurity region 120S may have a curvature. For example, the pair of first side walls SW1 of the first portion P1 of the first impurity region 120S, which are opposite to each other, may each have a curvature, and the pair of second side walls SW2 of the second portion P2, which are opposite to each other, may have a flat shape. For example, in a direction toward the bit line BL′, each of the pair of first side walls SW1 of the first portion P1 of the first impurity region 120S, which are opposite to each other, may have a shape that is rounded so that the pair of first side walls SW1 are closer in a direction in which the pair of first side walls SW1 of the first portion P1 of the first impurity region 120S are opposite to each other. In other words, the pair of first side walls SW1 of the first portion P1 of the first impurity region 120S, which are opposite to each other, may have a concave shape. For example, the pair of first side walls SW1 of the first portion P1 of the first impurity region 120S, which are opposite to each other, may have an elliptical arc shape in the layout. The pair of second side walls SW2 of the second portion P2, which are opposite to each other, may extend to be substantially parallel to each other.

In some embodiments, a pair of third side walls B_SW′ of the bit line BL′, which are opposite to each other in the second horizontal direction (Y direction), may each have a curvature. For example, in a direction away from the semiconductor pattern 120, each of the pair of third side walls B_SW′ of the bit line BL′, which are opposite to each other, may have a shape that is rounded so that the pair of third side walls B_SW′ are closer in a direction in which the pair of third side walls B_SW′ are opposite to each other. In other words, the pair of third side walls B_SW′ of the bit line BL′, which are opposite to each other, may have a concave shape. For example, the pair of third side walls B_SW′ of the bit line BL′, which are opposite to each other, may have an elliptical arc shape in the layout.

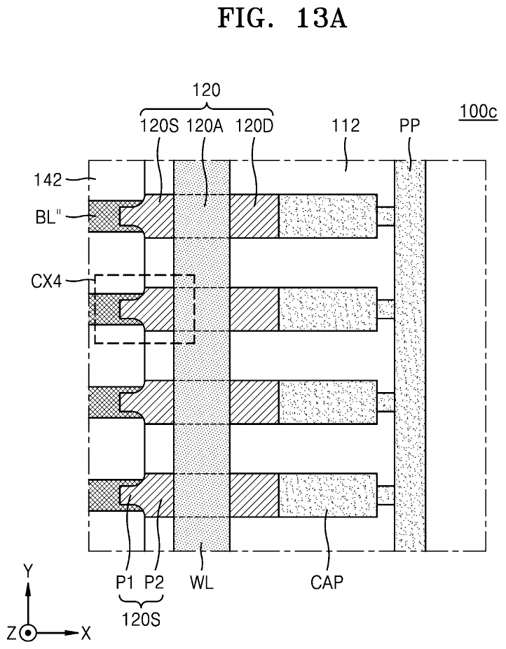

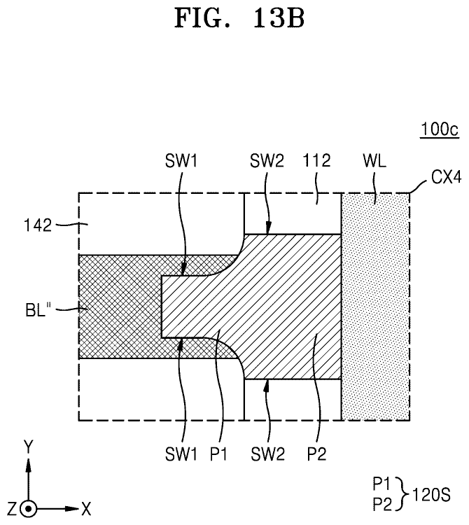

FIG. 13A is a diagram for explaining a semiconductor memory device 100c according to some embodiments.

FIG. 13A is a diagram schematically showing a portion of the semiconductor memory device 100c corresponding to a portion of the semiconductor memory device 100 shown in FIG. 5A.

FIG. 13B is an enlarged view of a portion CX4 of FIG. 13A.

The semiconductor memory device 100c shown in FIGS. 13A and 13B may be formed to be generally similar to the semiconductor memory device 100 described above, and thus, hereinafter, differences from the semiconductor memory device 100 are described in detail. In FIGS. 13A and 13B, the same reference numerals as those in FIGS. 4, 5A, 5B, 6A, 6B, 7, and 8 denote same components, and detailed descriptions thereof are omitted.

Referring to FIGS. 13A and 13B, in some embodiments, the first impurity region 120S of the semiconductor pattern 120 may have a horizontal width in the second horizontal direction (Y direction), which gradually varies in the first horizontal direction (X direction). The first impurity region 120S may include the first portion P1 that is in contact with a bit line BL″ and the second portion P2 spaced apart from the bit line BL″ with the first portion P1 therebetween.

In some embodiments, the bit line BL″ may extend to cover a portion of a pair of side walls of the first impurity region 120S of the semiconductor pattern 120. In the example of FIGS. 13A and 13B, unlike in FIG. 5B, the bit line BL″ may extend to cover the pair of first side walls SW1 of the first portion P1 of the first impurity region 120S of the semiconductor pattern 120, the pair of first side walls SW1 opposite to each other. However, the bit line BL″ may not extend to cover the pair of second side walls SW2 of the second portion P2 of the first impurity region 120S of the semiconductor pattern 120, the pair of second side walls SW2 opposite to each other.

According to embodiments of the present disclosure, by providing the semiconductor memory devices 100, 100a, 100b, and 100c each having a relatively small horizontal width (for example, the third horizontal width w3) of the bit line BL and a relatively small horizontal width (for example, the first horizontal width w1 of the first portion P1 of the first impurity region 120S) of a portion of the semiconductor pattern 120, which is adjacent to the bit line BL, it is possible to increase separation distances among the plurality of bit lines BL and separation distances among portions (for example, the first portions P1 of the first impurity regions 120S) of the plurality of semiconductor patterns 120, which are adjacent to the bit line BL. Thus, according to embodiments of the present disclosure, it is possible to relatively reduce parasitic capacitance induced by the plurality of bit lines BL and parasitic capacitance induced by the plurality of semiconductor patterns 120, and thereby, it is possible to provide a semiconductor memory device with improved reliability.

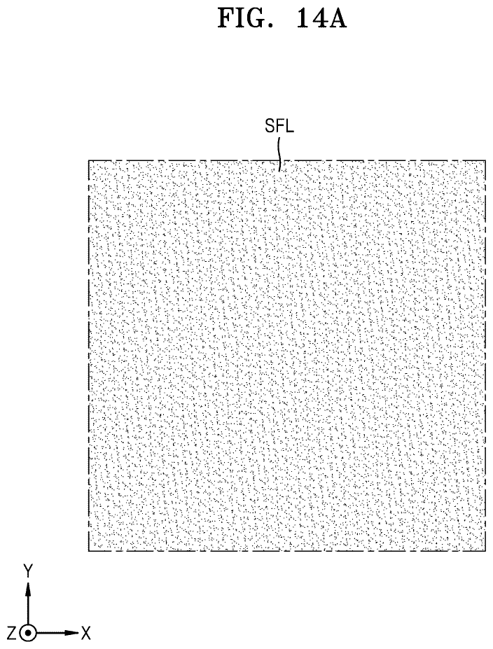

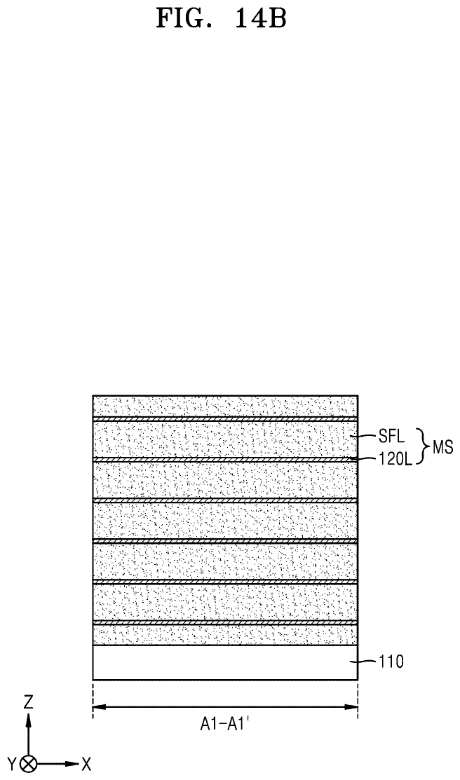

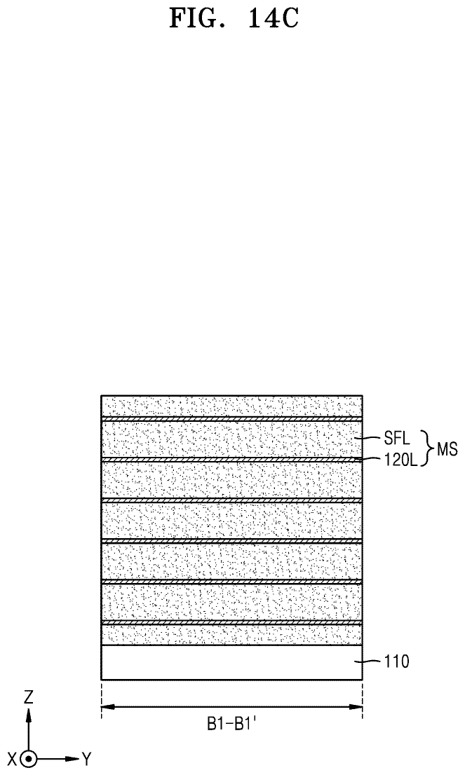

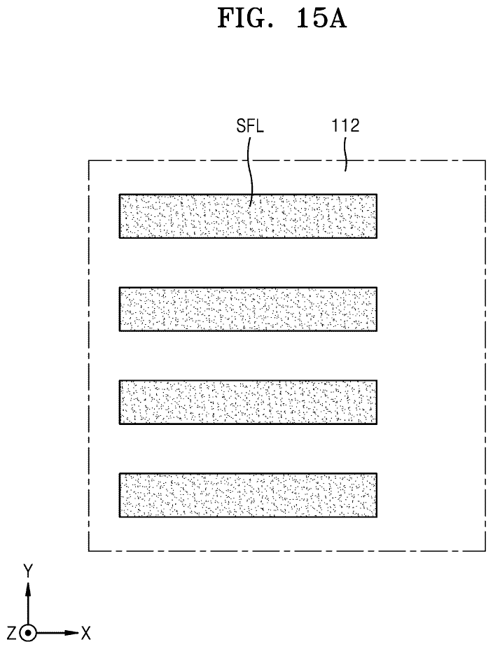

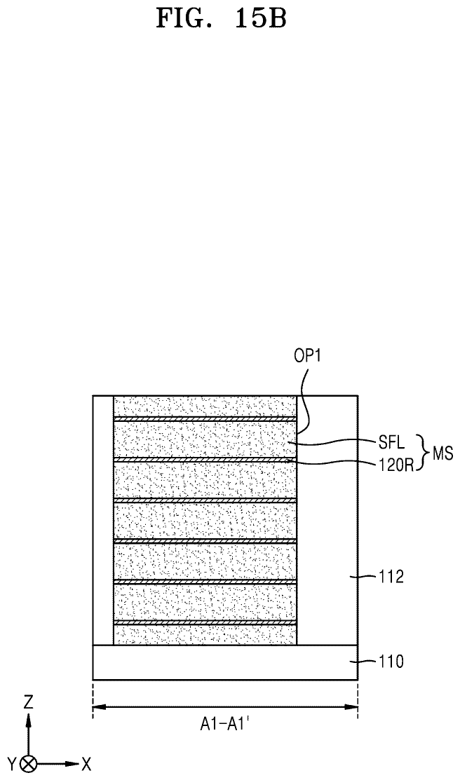

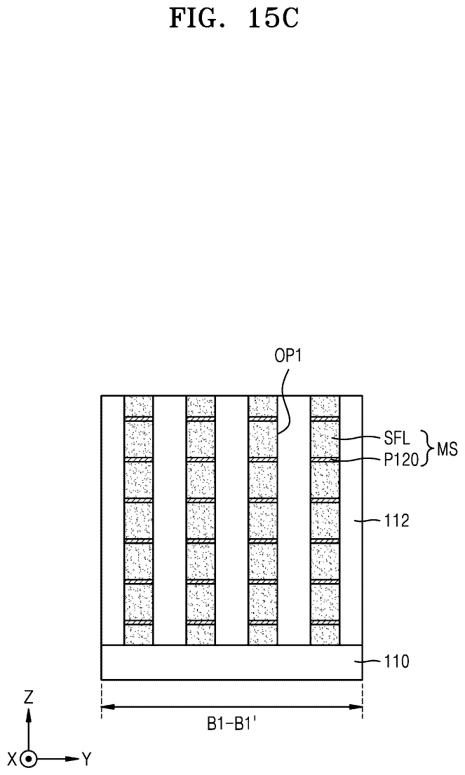

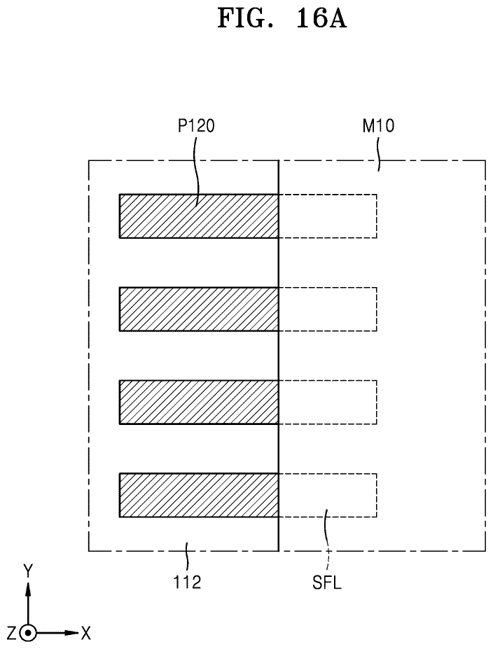

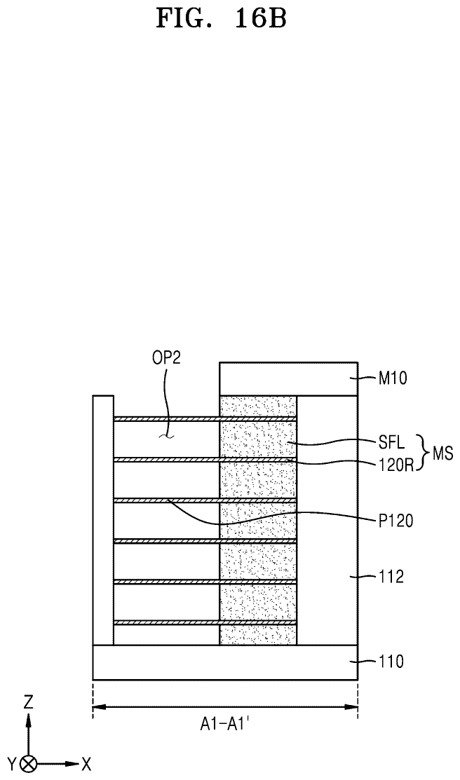

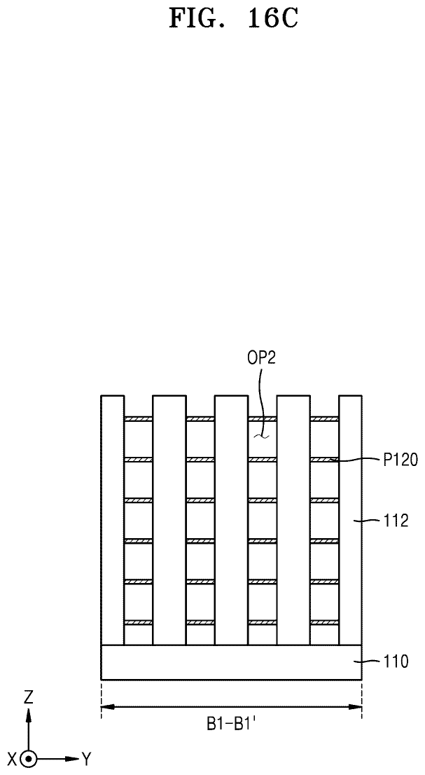

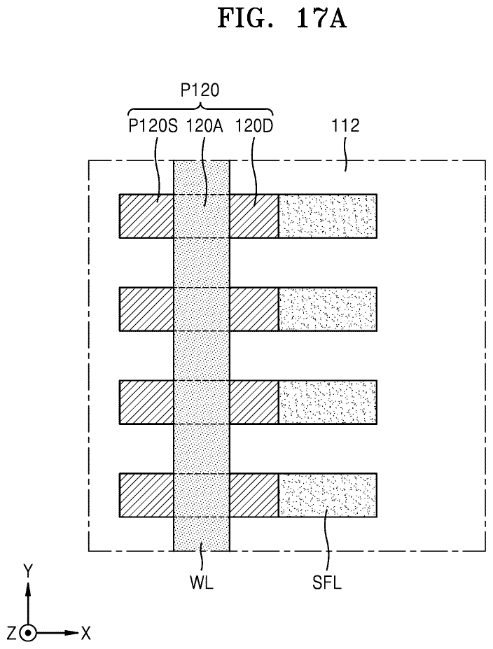

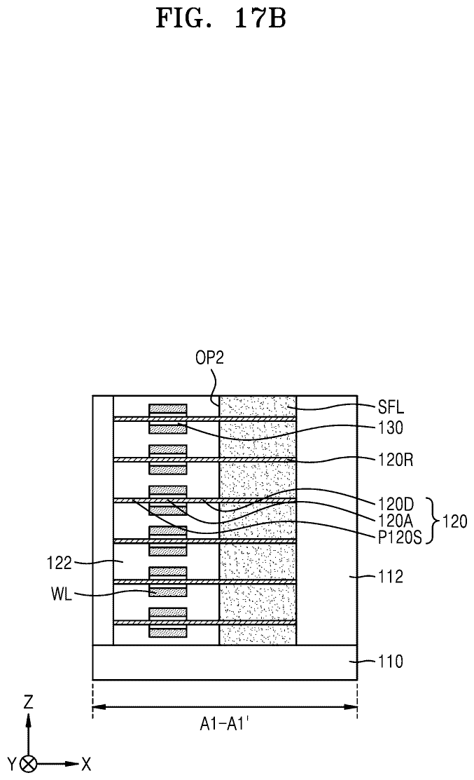

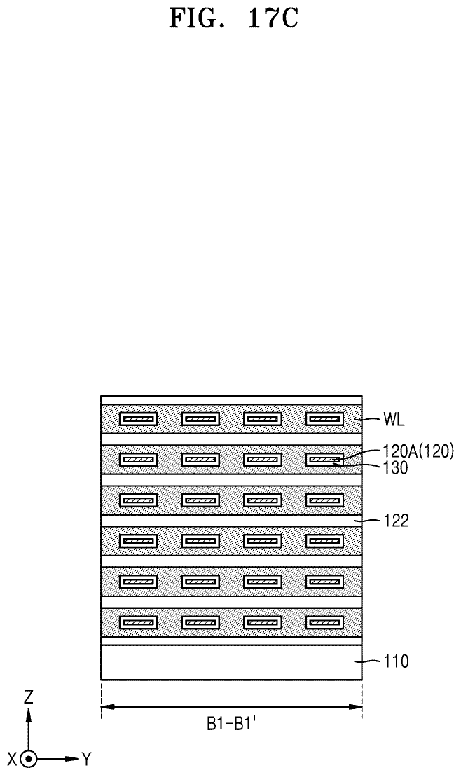

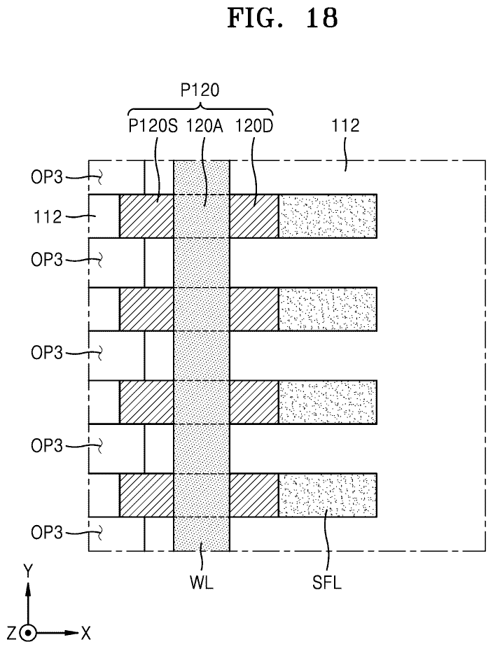

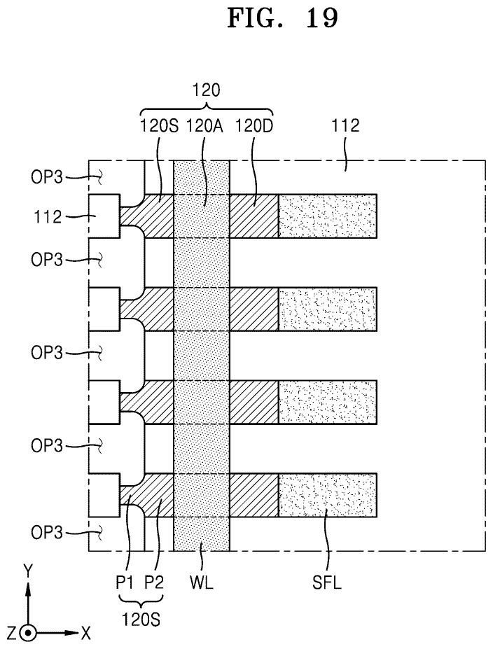

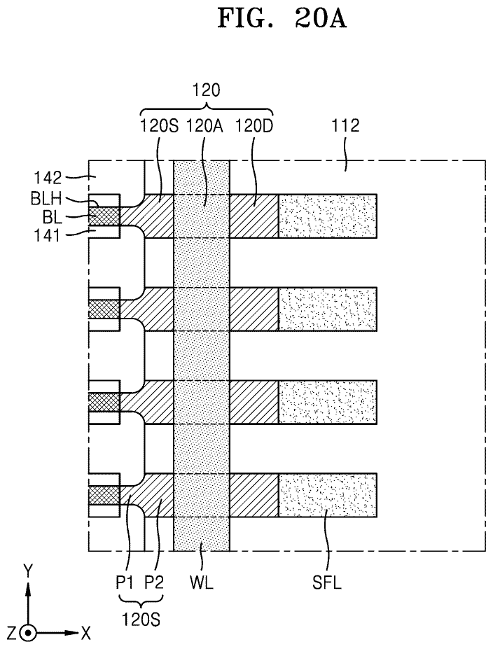

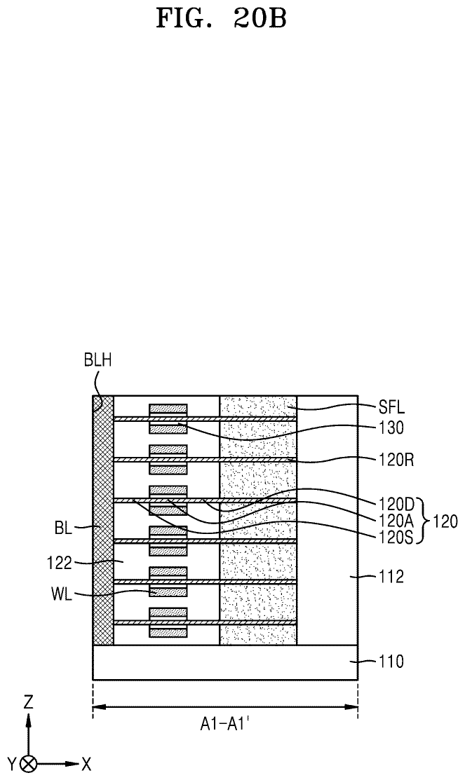

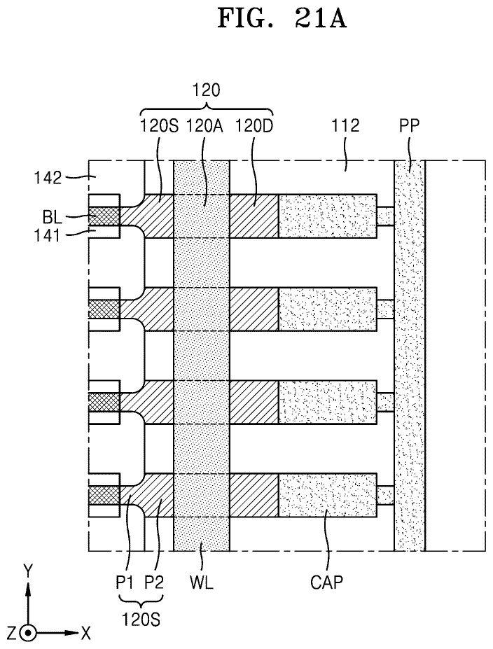

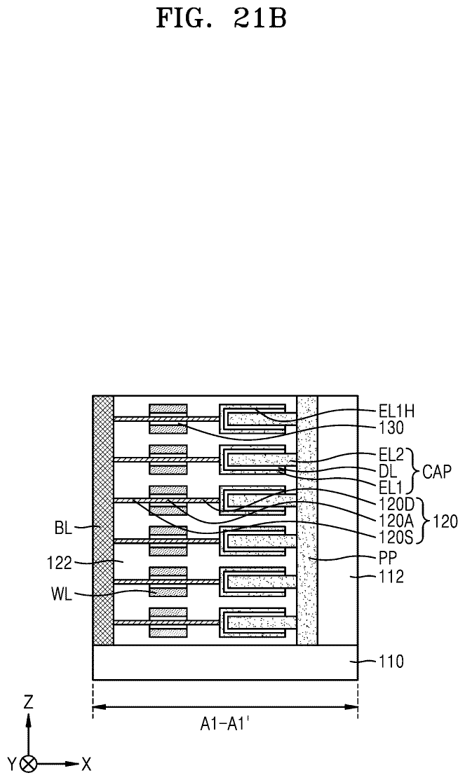

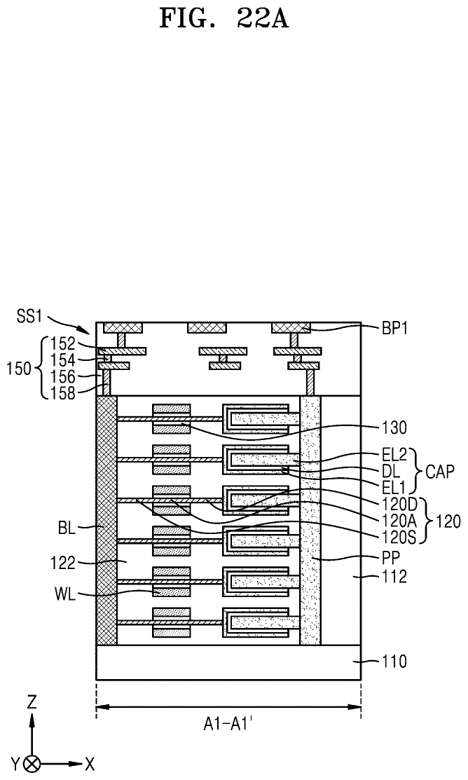

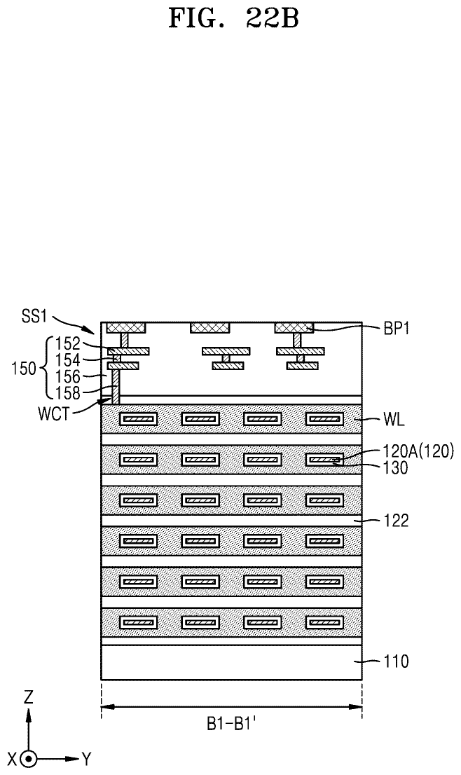

FIG. 14A, FIG. 14B, FIG. 14C, FIG. 15A, FIG. 15B, FIG. 15C, FIG. 16A, FIG. 16B, FIG. 16C, FIG. 17A, FIG. 17B, FIG. 17C, FIG. 18, FIG. 19, FIG. 20A, FIG. 20B, FIG. 21A, FIG. 21B, FIG. 22A, FIG. 22B, FIG. 23A, and FIG. 23B are schematic views showing a method of manufacturing a semiconductor memory device according to some embodiments.

In detail, FIGS. 14A, 15A, 16A, 17A, 18, 19, 20A, and 21A may each correspond to a portion of the semiconductor memory device shown in FIG. 5A; FIGS. 14B, 15B, 16B, 17B, 20B, 21B, 22A, and 23A may correspond to a cross-section taken along the line A1-A1′ of FIG. 4; and FIGS. 14C, 15C, 16C, 17C, 22B, and 23B may each correspond to a cross-section taken along the line B1-B1′ of FIG. 4.

Referring to FIGS. 14A, 14B, and 14C, a sacrificial mold layer SFL and a semiconductor layer 120L may be alternately and sequentially formed on the first substrate 110 to form a mold stack MS.

In some embodiments, the sacrificial mold layer SFL and the semiconductor layer 120L may include materials having etch selectivities relative to each other. For example, each of the sacrificial mold layer SFL and the semiconductor layer 120L may include a single-crystal layer of a group IV semiconductor, a group II-VI compound semiconductor, or a group III-V compound semiconductor, and the sacrificial mold layer SFL and the semiconductor layer 120L may include different materials from each other. In an embodiment, the sacrificial mold layer SFL may include SiGe, and the semiconductor layer 120L may include a single-crystal silicon. Each of the sacrificial mold layer SFL and the semiconductor layer 120L may have a thickness of several tens of nanometers (nm).

In some embodiments, the sacrificial mold layer SFL and the semiconductor layer 120L may be formed by an epitaxial process. For example, the epitaxial process may be vapor-phase epitaxy (VPE), a CVD process such as ultra-high vacuum chemical vapor deposition (UHV-CVD), molecular beam epitaxy, or a combination thereof. In the epitaxial process, liquid or gaseous precursors may be used as precursors required to form the sacrificial mold layer SFL and the semiconductor layer 120L.

Referring to FIGS. 15A, 15B, and 15C, a mask pattern (not shown) is formed on the mold stack MS, and the mask pattern is used as an etching mask to remove a portion of the mold stack MS to thereby form a first opening OP1. Afterwards, the filling insulating layer 112 may be formed in the first opening OP1.

In some embodiments, due to the formation of the first opening OP1, a plurality of preliminary semiconductor patterns P120 may be formed from the semiconductor layer 120L. Herein, the plurality of preliminary semiconductor patterns P120 may be formed by patterning portions of the semiconductor layer 120L.

Referring to FIGS. 16A, 16B, and 16C, a second opening OP2 may be formed between the plurality of semiconductor patterns 120 by removing the sacrificial mold layer SFL.

In some embodiments, a mask pattern M10 may be formed on the mold stack MS, a portion of the sacrificial mold layer SFL, which is not covered by the mask pattern M10, may be removed, and portions of the sacrificial mold layer SFL arranged at a position that vertically overlaps the mask pattern M10 may remain without being removed. Herein, a portion of the preliminary semiconductor pattern P120, which is covered by the sacrificial mold layer SFL, may be referred to as a residual pattern 120R. The mask pattern M10 may be arranged on a structure in which the residual pattern 120R and the sacrificial mold layer SFL are alternately stacked.

In some embodiments, a process for removing the sacrificial mold layer SFL may be a wet etching process or a pullback process. For example, the process for removing the sacrificial mold layer SFL may be an etching process using an etch selectivity between the sacrificial mold layer SFL and the semiconductor layer 120L. For example, in the wet etching process or the pullback process, the etch rate of the plurality of preliminary semiconductor patterns P120 may be relatively low, and the etch rate of the sacrificial mold layer SFL may be relatively high.

Referring to FIGS. 17A, 17B, and 17C, the gate insulating layer 130 and the word line WL may be sequentially formed on top, side, and bottom surfaces of the plurality of preliminary semiconductor patterns P120 within the second opening OP2.

For example, the gate insulating layer 130 may be conformally arranged to surround the plurality of preliminary semiconductor patterns P120, and the word line WL may surround the plurality of preliminary semiconductor patterns P120 on the gate insulating layer 130 and may be arranged to extend in the second horizontal direction (Y direction).

In some embodiments, the gate insulating layer 130 and the word line WL arranged at both ends (for example, both ends in the first horizontal direction (X direction)) of each of the plurality of preliminary semiconductor patterns P120 within the second opening OP2 may be partially removed. In some embodiments, first, a protective layer (not shown) may be formed to cover both ends of each of the plurality of preliminary semiconductor patterns P120 within the second opening OP2, and then, the gate insulating layer 130 and the word line WL may be formed to surround a central portion of each of the plurality of preliminary semiconductor patterns P120 and then the protective layer may be removed, such that both ends of each of the plurality of preliminary semiconductor patterns P120 may be exposed again without being covered by the gate insulating layer 130 and the word line WL.

Afterwards, a preliminary first impurity region P120S and the second impurity region 120D may be formed. The preliminary first impurity region P120S and the second impurity region 120D may be formed at both ends of the preliminary semiconductor pattern P120, which are exposed by partially removing the gate insulating layer 130 and the word line WL.

Afterwards, the mold insulating layer 122 may be formed to occupy the inside of the second opening OP2. In some embodiments, the mold insulating layer 122 may be arranged between two word lines WL that are adjacent to each other in the vertical direction (Z direction) and between ends of two preliminary semiconductor patterns P120 that are adjacent to each other in the vertical direction (Z direction).

In some embodiments, a portion of the word line WL may be removed to form a word line pad (not shown). Word line pads (not shown) may be arranged to have a step shape, and for example, a word line pad (not shown) connected to one word line WL may be arranged apart from a word line pad (not shown) connected to another word line WL arranged under the one word line WL, in the second horizontal direction (Y direction).

Referring to FIG. 18, a plurality of third openings OP3 may be formed to partially expose an upper surface of the first substrate 110 (of FIG. 17B) by penetrating the results of FIGS. 17A, 17B, and 17C in the vertical direction (Z direction). Each of the plurality of third openings OP3 may be formed by etching the filling insulating layer 112 between the plurality of preliminary semiconductor patterns P120. Each of the plurality of third openings OP3 may expose one end of the preliminary first impurity region P120S of each of the plurality of preliminary semiconductor patterns P120. The one end of the preliminary first impurity region P120S of each of the plurality of preliminary semiconductor patterns P120, which is exposed by the plurality of third openings OP3, may be a portion that is spaced apart from the word line WL.

Referring to FIG. 19, an isotropic etching process, for example, a wet etching process, may be performed to etch the one end of the preliminary first impurity region P120S of each of the plurality of preliminary semiconductor patterns P120, which is exposed via the plurality of third openings OP3 of FIG. 18. For example, a process for etching the one end of the preliminary first impurity region P120S of each of the plurality of preliminary semiconductor patterns P120 may be an etching process using an etch selectivity of the filling insulating layer 112 and the mold insulating layer 122 with respect to the preliminary semiconductor pattern P120. The first impurity region 120S including a portion of which the horizontal width in the second horizontal direction (Y direction) continuously varies may be formed by etching the one end of the preliminary first impurity region P120S via the isotropic etching process.

A portion that remains after etching the one end of the preliminary first impurity region P120S via the isotropic etching process is formed as the first impurity region 120S, and thus, the first impurity region 120S may include the first portion P1 which has a relatively small horizontal width in the second horizontal direction (Y direction) and the second portion P2 which has a relatively large horizontal width in the second horizontal direction (Y direction).

In some embodiments, a pair of first side walls of the first portion P1 of the first impurity region 120S, which are opposite to each other, may each have a curvature, and a pair of second side walls of the second portion P2 of the first impurity region 120S, which are opposite to each other, may have a flat shape. For example, in a direction toward the bit line BL, each of the pair of first side walls of the first portion P1 of the first impurity region 120S, which are opposite to each other, may have a shape that is rounded so that the pair of first side walls are closer in a direction in which the pair of first side walls of the first portion P1 of the first impurity region 120S are opposite to each other.

Referring to FIGS. 20A and 20B, in the result of FIG. 19, in order to form the outer insulating spacer 142 within the third opening OP3, an insulating material including silicon oxide, silicon oxynitride, silicon nitride, carbon-containing silicon oxide, carbon-containing silicon oxynitride, carbon-containing silicon nitride, or a combination thereof may be deposited within the third opening OP3. Alternatively, in order to form the outer insulating spacer 142 including an air gap, a film covering the third opening OP3 may be deposited on the third opening OP3 via a subsequent process.

Afterwards, a bit line opening BLH penetrating, in the vertical direction (Z direction), a portion of the filling insulating layer 112, which is arranged between each of a plurality of outer insulating spacers 142, may be formed, and the bit line BL may be formed within the bit line opening BLH. After the bit line BL is formed, a portion of the filling insulating layer 112 (of FIG. 19) may remain on a side wall of the bit line BL to form the inner insulating spacer 141. The insulating spacer may be formed via various processes, and for example, the inner insulating spacer 141 may be formed first, and then, the outer insulating spacer 142 may be formed.

The horizontal width of the bit line BL in the second horizontal direction (Y direction) may be similar to or relatively less than the horizontal width of the first portion P1 of the first impurity region 120S in the second horizontal direction (Y direction). The horizontal width of the bit line BL in the second horizontal direction (Y direction) may be less than the horizontal width of the second portion P2 in the second horizontal direction (Y direction).

Referring to FIGS. 21A and 21B, the sacrificial mold layer SFL and the residual pattern 120R may be removed, and the cell capacitor CAP may be formed at positions where the sacrificial mold layer SFL and the residual pattern 120R have been removed.

In some embodiments, the cell capacitor CAP may include the first electrode EL1, the capacitor dielectric layer DL, and the second electrode EL2. The first electrode EL1 may be electrically connected to the second impurity region 120D of the semiconductor pattern 120 and may have an internal space EL1H (e.g., a filled groove or filled cavity) extending in the first horizontal direction (X direction). The capacitor dielectric layer DL may be conformally arranged within the internal space EL1H, and the internal space EL1H may be occupied by the second electrode EL2.

Afterwards, the plate electrode PP that is electrically connected to the second electrode EL2 and extends in the second horizontal direction (Y direction) may be formed.

Referring to FIGS. 22A and 22B, the upper wiring structure 150 may be formed. The upper wiring structure 150 may include the wiring layer 152, the via 154, the interlayer insulating layer 156, and a contact 158. For example, the contact 158 may be electrically connected to the bit line BL, the word line WL, and the plate electrode PP. Afterwards, the first bonding pad BP1 that is coplanar with the top surface of the interlayer insulating layer 156 may be formed on the upper wiring structure 150.

Referring to FIGS. 23A and 23B, the second stack structure SS2 may be prepared.

In some embodiments, the second stack structure SS2 may include the second substrate 310, the peripheral circuit transistor 320 arranged on the second substrate 310, the front wiring structure 330 that covers the peripheral circuit transistor 320 on the top surface of the second substrate 310, and the rear wiring structure 340 arranged on the bottom surface of the second substrate 310.

In some embodiments, the peripheral circuit transistor 320 may be formed on a first surface (or top surface) of the second substrate 310, the front wiring structure 330 may be formed on the first surface of the second substrate 310, a carrier substrate may be attached onto the front wiring structure 330, and then, a second surface (or bottom surface) of the second substrate 310 may be grinded down to thin the second substrate 310. Afterwards, the second stack structure SS2 may be completed by forming the rear wiring structure 340 and the second bonding pad BP2 on the second surface of the second substrate 310.

Afterwards, the second stack structure SS2 and the first stack structure SS1 may be bonded to each other, and at this time, the first bonding pad BP1 of the first stack structure SS1 and the second bonding pad BP2 of the second stack structure SS2 may be bonded to each other, and the top surface of the interlayer insulating layer 156 and the bottom surface of the peripheral circuit insulating layer 346 may be bonded to each other. Accordingly, the semiconductor memory device 100 (of FIGS. 4, 5A, 5B, 6A, 6B, 7, and 8) may be formed.

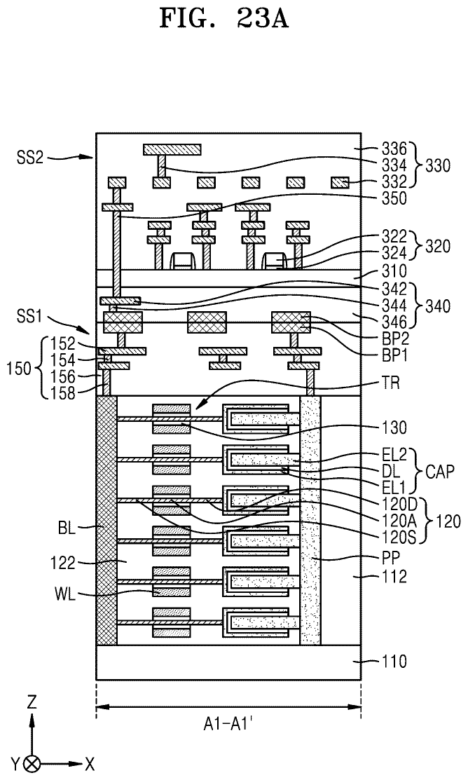

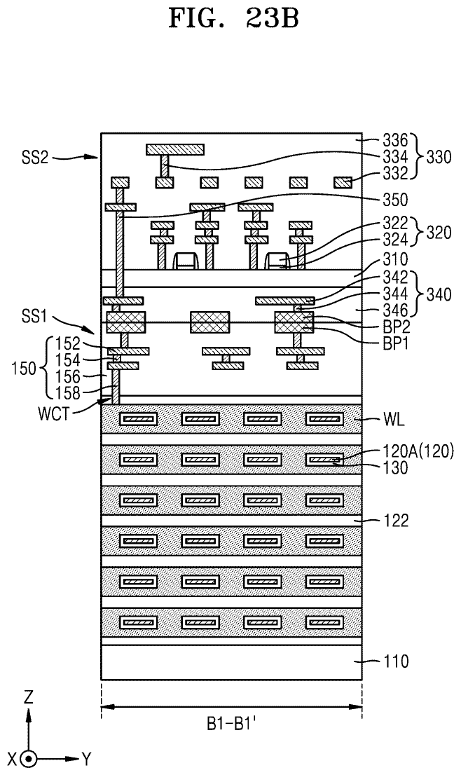

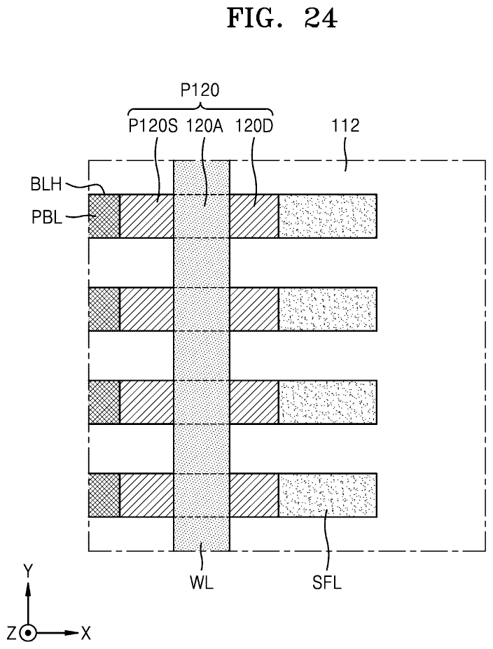

FIG. 24 to FIG. 26 are schematic views showing a method of manufacturing a semiconductor memory device according to some embodiments.

Referring to FIG. 24, in the results of FIGS. 17A, 17B, and 17C, the bit line opening BLH penetrating a portion of the filling insulating layer 112 in the vertical direction (Z direction) may be formed. The preliminary first impurity region P120S of the preliminary semiconductor pattern P120 may be exposed by the bit line opening BLH. Afterwards, a preliminary bit line PBL may be formed in the bit line opening BLH.

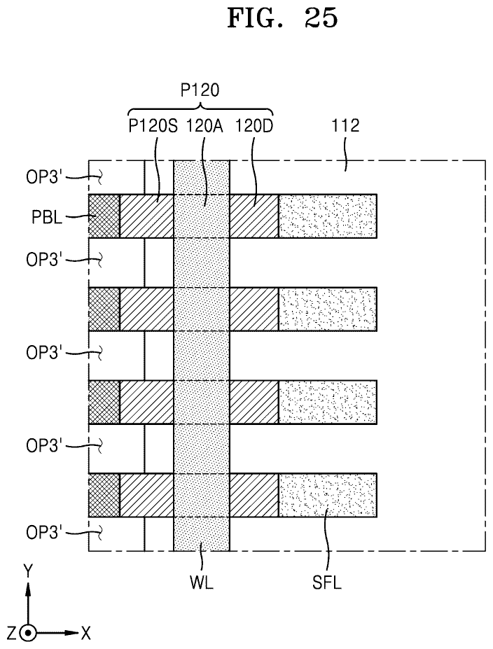

Referring to FIG. 25, a plurality of third openings OP3′ may be formed to partially expose the upper surface of the first substrate 110 (of FIG. 17B) by penetrating the result of FIG. 24 in the vertical direction (Z direction). Each of the plurality of third openings OP3′ may be formed by etching the filling insulating layer 112 between a plurality of preliminary bit lines PBL. The plurality of third openings OP3′ may expose one end of the preliminary first impurity region P120S of each of the plurality of preliminary semiconductor patterns P120. The one end of the preliminary first impurity region P120S of each of the plurality of preliminary semiconductor patterns P120, which is exposed by the plurality of third openings OP3′, may be a portion that is spaced apart from the word line WL. In addition, each of the plurality of third openings OP3′ may expose side portions of the plurality of preliminary bit lines PBL.

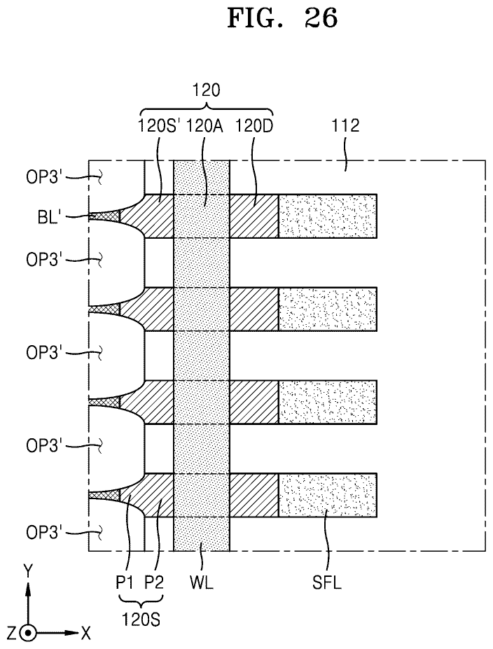

Referring to FIG. 26, an isotropic etching process, for example, a wet etching process, may be performed to etch the one end of the preliminary first impurity region P120S of the preliminary semiconductor pattern P120, which is exposed via the plurality of third openings OP3′ of FIG. 25, and the side portions of the plurality of preliminary bit lines PBL. For example, a process for etching the one end of the preliminary first impurity region P120S of the preliminary semiconductor pattern P120 and the side portions of the plurality of preliminary bit lines PBL may be an etching process using an etch selectivity of the filling insulating layer 112 and the mold insulating layer 122 with respect to the preliminary semiconductor pattern P120 and the preliminary bit line PBL.

The first impurity region 120S including a portion of which the horizontal width in the second horizontal direction (Y direction) continuously varies may be formed by etching the one end of the preliminary first impurity region P120S via the isotropic etching process. The bit line BL′ of which the horizontal width in the second horizontal direction (Y direction) continuously varies may be formed by etching the side portion of the preliminary bit line PBL via the isotropic etching process. The one end of the preliminary first impurity region P120S and the side portions of the plurality of preliminary bit lines PBL are simultaneously etched, and thus, a side wall of the bit line BL′ in the second horizontal direction (Y direction) and a side wall of the first impurity region 120S in the second horizontal direction (Y direction) may be smoothly and continuously connected to each other.

Afterwards, in order to form the outer insulating spacer 142 in a third opening OP3′, an insulating material including silicon oxide, silicon oxynitride, silicon nitride, carbon-containing silicon oxide, carbon-containing silicon oxynitride, carbon-containing silicon nitride, or a combination thereof may be deposited within the third opening OP3′. Alternatively, in order to form the outer insulating spacer 142 including an air gap, a film covering the third opening OP3′ may be deposited on the third opening OP3′ via a subsequent process. Accordingly, a structure similar to that shown in FIGS. 12A and 12B may be formed.

Afterwards, by performing a process similar to the process described with reference to FIGS. 21A, 21B, 22A, 22B, 23A, and 23B, the first stack structure SS1 of FIGS. 23A and 23B may be formed, and the second stack structure SS2 may be arranged on the first stack structure SS1. Accordingly, the semiconductor memory device 100b (of FIGS. 12A and 12B) may be formed.

While the invention has been particularly shown and described with reference to embodiments thereof, it will be understood that various changes in form and details may be made therein without departing from the spirit and scope of the following claims.

What is claimed is:

1. A semiconductor memory device comprising:
a substrate;
a semiconductor pattern extending in a first horizontal direction on the substrate and comprising a channel region, a first impurity region, and a second impurity region, wherein the first impurity region and the second impurity region are arranged in the first horizontal direction with the channel region therebetween;
a word line surrounding the channel region of the semiconductor pattern and extending in a second horizontal direction crossing the first horizontal direction;
a bit line in contact with the first impurity region of the semiconductor pattern and extending in a vertical direction; and
a cell capacitor in contact with the second impurity region of the semiconductor pattern,
wherein the first impurity region of the semiconductor pattern comprises a first portion in contact with the bit line and a second portion connected to the first portion,
wherein the first portion has a varying horizontal width in the second horizontal direction, and
wherein the varying horizontal width of the first portion continuously varies along the first horizontal direction.

2. The semiconductor memory device of claim 1, wherein the varying horizontal width of the first portion increases along the first horizontal direction toward the second portion.

3. The semiconductor memory device of claim 1, wherein the second portion has a horizontal width in the second horizontal direction, and
wherein the horizontal width of the second portion is greater than a minimum value of the varying horizontal width.

4. The semiconductor memory device of claim 3, wherein the bit line has a horizontal width in the second horizontal direction, and
wherein the horizontal width of the bit line is less than the horizontal width of the second portion and is equal to the minimum value of the varying horizontal width.

5. The semiconductor memory device of claim 1, wherein the bit line has a horizontal width in the second horizontal direction, and
wherein the horizontal width of the bit line continuously varies along the first horizontal direction.

6. The semiconductor memory device of claim 1, wherein the first portion of the semiconductor pattern comprises a pair of first side walls opposite each other in the second horizontal direction, and
wherein each of the pair of first side walls has a curvature.

7. The semiconductor memory device of claim 1, wherein the bit line comprises a pair of side walls opposite each other in the second horizontal direction, and
wherein each of the pair of side walls has a curvature.

8. The semiconductor memory device of claim 1, wherein the first portion of the semiconductor pattern comprises a pair of first side walls opposite each other in the second horizontal direction,
wherein the second portion of the semiconductor pattern comprises a pair of second side walls opposite each other in the second horizontal direction, and
wherein the bit line extends to cover at least a portion of each of the pair of first side walls.

9. The semiconductor memory device of claim 1, wherein the bit line is one of a plurality of bit lines,
wherein the plurality of bit lines are arranged apart from each other in the second horizontal direction, and
wherein an insulating spacer is arranged between each two adjacent bit lines of the plurality of bit lines.

10. The semiconductor memory device of claim 9, wherein the insulating spacer comprises silicon oxide, silicon oxynitride, silicon nitride, carbon-containing silicon oxide, carbon-containing silicon oxynitride, carbon-containing silicon nitride, or a combination thereof, or comprises an air gap.

11. A semiconductor memory device comprising:
a substrate;
a plurality of word lines arranged apart from each other in a first horizontal direction on the substrate and extending in a second horizontal direction crossing the first horizontal direction;
a bit line arranged between a first set of word lines of the plurality of word lines and a second set of word lines of the plurality of word lines and extending in a vertical direction;
a plurality of cell capacitors spaced apart from the bit line with the first set of word lines of the plurality of word lines therebetween; and
a plurality of semiconductor patterns, a respective semiconductor pattern comprising: a channel region overlapping a respective world line of the word lines of the first set of word lines in the vertical direction, a first impurity region connected to the bit line, and a second impurity region connected to a respective cell capacitor of the plurality of cell capacitors,
wherein:
each first impurity region comprises a first portion in contact with the bit line and a second portion spaced apart from the bit line with the first portion therebetween,
the first portion has a horizontal width in the second horizontal direction,
the second portion has a horizontal width in the second horizontal direction that is greater than a minimum value of the horizontal width in the second horizontal direction of the first portion, and
the bit line has a horizontal width in the second horizontal direction that is less than the horizontal width in the second horizontal direction of the second portion.

12. The semiconductor memory device of claim 11, wherein the horizontal width in the second horizontal direction of the first portion continuously varies along the first horizontal direction.

13. The semiconductor memory device of claim 11, wherein the horizontal width in the second direction of the first portion increases along a direction toward the second portion.

14. The semiconductor memory device of claim 11, wherein the horizontal width in the second horizontal direction of the bit line continuously varies along the first horizontal direction.

15. The semiconductor memory device of claim 11, wherein the horizontal width of the bit line in the second direction increases along a direction toward the first portion.

16. The semiconductor memory device of claim 11, wherein each of the plurality of cell capacitors comprises a first electrode, a capacitor dielectric layer, and a second electrode, and
wherein the first electrode is electrically connected to the second impurity region of the semiconductor pattern and comprises an internal cavity extending in the first horizontal direction.

17. A semiconductor memory device comprising:
a substrate;
a semiconductor pattern extending in a first horizontal direction on the substrate and comprising a channel region, a first impurity region, and a second impurity region, wherein the first impurity region and the second impurity region are arranged in the first horizontal direction with the channel region therebetween;
a word line surrounding the channel region of the semiconductor pattern and extending in a second horizontal direction crossing the first horizontal direction;
a bit line in contact with the first impurity region of the semiconductor pattern and extending in a vertical direction; and
a cell capacitor in contact with the second impurity region of the semiconductor pattern,
wherein the first impurity region of the semiconductor pattern comprises a first portion in contact with the bit line and a second portion spaced apart from the bit line with the first portion therebetween,
wherein the first portion has first side walls opposite to each other in the second horizontal direction,
wherein the second portion has second side walls opposite to each other in the second horizontal direction,
wherein each of the first side walls has a curvature, and
wherein the second side walls are flat.

18. The semiconductor memory device of claim 17, wherein the semiconductor pattern comprises:
a seed layer comprising a semiconductor material and extending in the first horizontal direction, and
an epitaxial layer arranged to surround the seed layer and extending in the first horizontal direction.

19. The semiconductor memory device of claim 17, further comprising a gate insulating layer arranged between the semiconductor pattern and the word line,
wherein the gate insulating layer conformally surrounds the channel region.

20. The semiconductor memory device of claim 17, wherein the cell capacitor comprises a first electrode, a capacitor dielectric layer, and a second electrode,
wherein the first electrode is electrically connected to the second impurity region of the semiconductor pattern and comprises an internal cavity extending in the first horizontal direction,
wherein the capacitor dielectric layer is conformally arranged along an internal wall of the internal cavity, and
wherein the internal cavity is occupied by the second electrode.
